(19) United States
(12) Patent Application Publication
(10) Pub. No.: US 2024/0324402 A1
(43) Pub. Date: Sep. 26, 2024

(54) DISPLAY APPARATUS AND METHOD OF MANUFACTURING DISPLAY APPARATUS

(71) Applicants: Samsung Display Co., LTD., Yongin-si (KR); SEKONIX CO., LTD., Dongducheon-si (KR)

(72) Inventors: Kyungmin KIM, Yongin-si (KR); Jungchul SEO, Asan-si (KR); Chanhee LEE, Asan-si (KR)

(21) Appl. No.: 18/614,456

(22) Filed: Mar. 22, 2024

(30) Foreign Application Priority Data
Mar. 24, 2023 (KR) 10-2023-0039133
Jun. 29, 2023 (KR) 10-2023-0084506

(51) Int. Cl. H10K 59/80; H10K 59/12; H10K 71/40

(52) U.S. Cl. CPC H10K 59/872; H10K 59/1201; H10K 59/873; H10K 71/40

(57) ABSTRACT

A display apparatus includes a display panel including a substrate including a center area and a corner area arranged at a corner of the center area, and a resin layer arranged on the display panel, wherein the corner area includes a plurality of extension areas and a separation area between the plurality of extension areas, the plurality of extension areas extending in a direction away from the center area, and the resin layer includes a plurality of resin layer extension areas overlapping the plurality of extension areas.

This application claims priority to Korean Patent Application No. 10-2023-0039133, filed on Mar. 24, 2023, and Korean Patent Application No. 10-2023-0084506, filed on Jun. 29, 2023, and all the benefits accruing therefrom under 35 U.S.C. § 119, the content of which in its entirety is herein incorporated by reference.

### BACKGROUND

### 1. Field

Embodiments relate to a display apparatus and a method of manufacturing the display apparatus.

### 2. Description of the Related Art

Recently, electronic devices are being widely used. Electronic devices are used in various ways, such as mobile electronic devices and fixed electronic devices, and these electronic devices include a display apparatus capable of providing visual information, such as images or videos, to users in order to support various functions.

Recently, as other components for driving display apparatuses are being miniaturized, the proportion occupied by display apparatuses in electronic devices is gradually increasing, and structures that are bent to have a predetermined angle from a flat state or folded or bent around an axis are being developed.

### SUMMARY

A display apparatus that is bent at a predetermined angle has a problem in that cracks may occur in the display apparatus, e.g., a display panel, during bending of the display apparatus.

Embodiments include a display apparatus for preventing defects such as cracks and a method of manufacturing the display apparatus. Embodiments set forth herein are examples, and embodiments of the disclosure are not limited thereto.

Additional features will be set forth in part in the description which follows and, in part, will be apparent from the description, or may be learned by practice of the presented embodiments of the disclosure.

According to embodiments, a display apparatus includes a display panel including a substrate including a center area and a corner area arranged at a corner of the center area, and a resin layer arranged on the display panel, wherein the corner area includes a plurality of extension areas extending in a direction away from the center area and a separation area between the plurality of extension areas, and the resin layer includes a plurality of resin layer extension areas overlapping the plurality of extension areas.

In an embodiment, a side surface of the resin layer may have an angle of 80 degrees to 100 degrees with respect to an upper surface of the substrate.

In an embodiment, the resin layer may be a cured product of a resin composition including a urethane acrylate oligomer, an epoxy acrylate oligomer, a polyfunctional acrylate monomer, a bisphenol monomer, a low molecular weight ethylene glycol monomer, and a photoinitiator.

In an embodiment, the polyfunctional acrylate monomer may have three or four functional groups.

In an embodiment, the resin composition may include, based on a total weight of the resin composition, about 5 weight percent (wt %) to about 15 wt % of the urethane acrylate oligomer, about 5 wt % to about 15 wt % of the epoxy acrylate oligomer, about 20 wt % to about 35 wt % of the polyfunctional acrylate monomer, about 20 wt % to about 25 wt % of the bisphenol monomer, about 15 wt % to about 25 wt % of the low molecular weight ethylene glycol monomer, and about 3 wt % to about 5 wt % of the photoinitiator.

In an embodiment, the resin composition may further include about 2 wt % to about 5 wt % of an additive based on the total weight of the resin composition.

In an embodiment, the resin layer may have a modulus of about 0.7 gigapascal (GPa) to about 1.5 GPa.

In an embodiment, the resin layer may have a thickness of about 130 micrometers (μm) to about 170 μm.

In an embodiment, the display panel may further include a display element, and an encapsulation layer arranged to cover the display element and including at least one inorganic encapsulation layer and at least one organic encapsulation layer, wherein the resin layer may be arranged on the encapsulation layer.

In an embodiment, the display apparatus may further include a cover window arranged on the resin layer, and an adhesive layer arranged between the resin layer and the cover window, wherein the cover window and the adhesive layer may overlap the separation area, and the resin layer may not overlap the separation area.

According to embodiments, a method of manufacturing a display apparatus includes forming a substrate layer on a support substrate, the substrate layer including a center area, a plurality of extension areas arranged at corners of the center area and extending in a direction away from the center area, and a separation area between the plurality of extension areas, forming a display element on the substrate layer, forming an encapsulation layer to cover the display element, and forming a resin layer having a thickness of about 130 μm to about 170 μm on the encapsulation layer.

In an embodiment, the forming of the resin layer may include forming the resin layer to be arranged within the plurality of extension areas in a plan view.

In an embodiment, the forming of the resin layer may further include applying a resin composition, and irradiating light to cure the resin composition.

In an embodiment, the curing of the resin composition may include preparing a mask including a first area and a second area, aligning the mask so that the first area corresponds to the separation area and the second area corresponds to the plurality of extension areas, and irradiating light.

In an embodiment, the resin composition may include a urethane acrylate oligomer, an epoxy acrylate oligomer, a polyfunctional acrylate monomer, a bisphenol monomer, a low molecular weight ethylene glycol monomer, and a photoinitiator.

In an embodiment, the resin composition may include, based on a total weight of the resin composition, about 5 wt % to about 15 wt % of the urethane acrylate oligomer, about 5 wt % to about 15 wt % of the epoxy acrylate oligomer, about 20 wt % to about 35 wt % of the polyfunctional acrylate monomer, about 20 wt % to about 25 wt % of the bisphenol monomer, about 15 wt % to about 25 wt % of the low molecular weight ethylene glycol monomer, and about 3 wt % to about 5 wt % of the photoinitiator.

In an embodiment, the method may further include removing at least a portion of the substrate layer from the separation area.

In an embodiment, the method may further include detaching the substrate layer from the support substrate, bending the plurality of extension areas, and arranging a cover window on the resin layer over the plurality of extension areas.

In an embodiment, the method may further include arranging an adhesive layer between the cover window and the resin layer, wherein the cover window and the adhesive layer may overlap the separation area, and the resin layer may not overlap the separation area.

In an embodiment, the resin layer may have a modulus of about 0.7 GPa to about 1.5 GPa.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic perspective view of an embodiment of a display apparatus;

FIG. 2A is a cross-sectional view of the display apparatus taken along line A-A′ of FIG. 1, FIG. 2B is a cross-sectional view of the display apparatus taken along line B-B′ of FIG. 1, and FIG. 2C is a cross-sectional view of the display apparatus taken along line C-C′ of FIG. 1;

FIG. 3 is a schematic plan view of an embodiment of a display panel that may be included in a display apparatus;

FIG. 4 is a schematic equivalent circuit diagram illustrating an embodiment of a display element and a sub-pixel circuit electrically connected thereto of a display apparatus;

FIG. 5 is an enlarged view of a portion D of the display panel of FIG. 3;

FIG. 6 is a cross-sectional view of the display panel taken along line E-E′ of FIG. 5;

FIG. 7 is a cross-sectional view of the display panel taken along line F-F′ of FIG. 5;

FIG. 8 is a cross-sectional view of the display panel taken along line G-G′ of FIG. 5;

FIG. 9A is a schematic plan view illustrating an embodiment of a method of manufacturing a display apparatus;

FIG. 9B is a cross-sectional view of the display apparatus taken along line H-H′ of FIG. 9A;

FIG. 10 is a schematic cross-sectional view illustrating an embodiment of a method of manufacturing a display apparatus;

FIG. 11 is a schematic cross-sectional view illustrating an embodiment of a method of manufacturing a display apparatus;

FIG. 12A is a schematic plan view illustrating an embodiment of a method of manufacturing a display apparatus;

FIG. 12B is a cross-sectional view of the display apparatus taken along line I-I′ of FIG. 12A;

FIG. 13 is a schematic cross-sectional view illustrating an embodiment of a method of manufacturing a display apparatus;

FIG. 14 is a schematic cross-sectional view illustrating an embodiment of a method of manufacturing a display apparatus;

FIG. 15 is a schematic plan view illustrating an embodiment of a method of manufacturing a display apparatus;

FIG. 16 is a schematic plan view illustrating an embodiment of a method of manufacturing a display apparatus;

FIG. 17 is a schematic cross-sectional view illustrating an embodiment of a method of manufacturing a display apparatus; and

FIG. 18 is a schematic cross-sectional view illustrating an embodiment of a method of manufacturing a display apparatus.

### DETAILED DESCRIPTION

Reference will now be made in detail to embodiments, illustrative embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of various modifications and alternative forms, embodiments thereof are shown by way of example in the drawings and will herein be described in detail. Effects and characteristics of the disclosure, and realizing methods thereof will become apparent by referring to the drawings and embodiments described in detail below. However, the disclosure is not limited to the embodiments disclosed hereinafter and may be realized in various forms.

It will be understood that the terms “first,” “second,” etc. may be used herein to describe various components, these components should not be limited by these terms. These components are only used to distinguish one component from another.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or element is referred to as being formed “on” another layer, area, or element, it can be directly or indirectly formed on the other layer, region, or element. That is, for example, intervening layers, regions, or elements may be present.

In the specification, an expression such as “A and/or B” indicates A, B, or A and B. Also, an expression such as “at least one of A and B” indicates A, B, or A and B.

In the following embodiments, the meaning of “extending in a first or second direction” includes not only extending in a straight line but also extending in a zigzag or curved line in the first or second direction.

In the following embodiments, “in a plan view” means the subject part is viewed from above, and “in a cross-sectional view” means a cross-section of the subject part cut vertically is viewed from the side. In the following embodiments, when referring to “overlapping”, this includes overlapping “in a plan view” and overlapping “in a cross-sectional view”.

Hereinafter, the embodiments of the disclosure will be described in detail with reference to the accompanying drawings. In the descriptions, like reference numerals refer to the like elements and the same descriptions will not be repeated.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

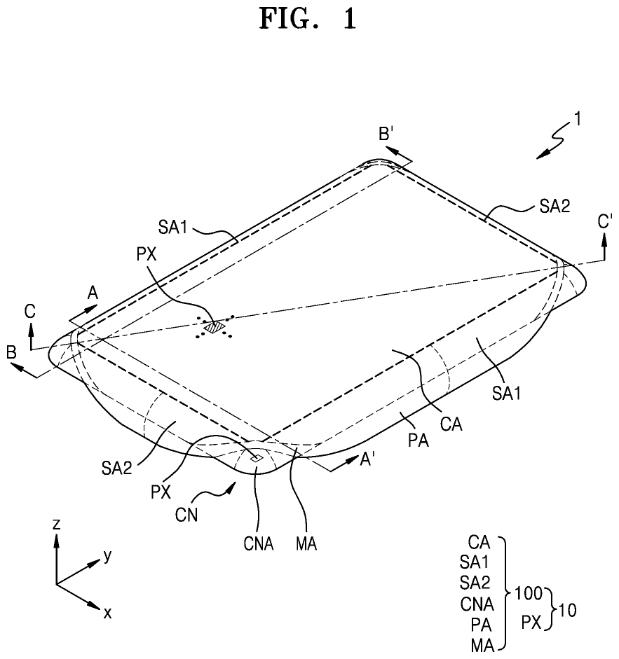

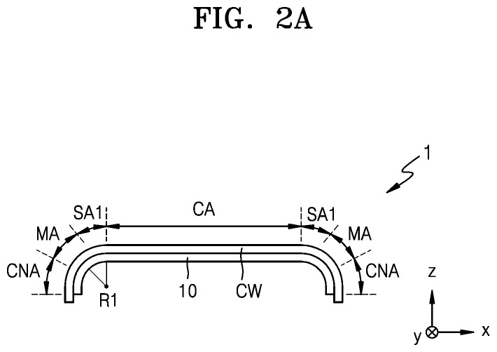

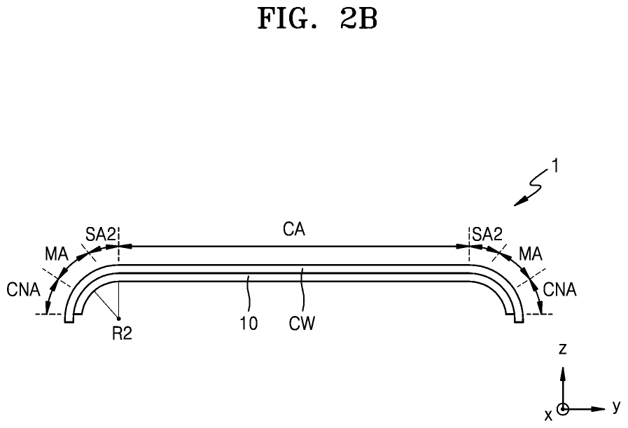

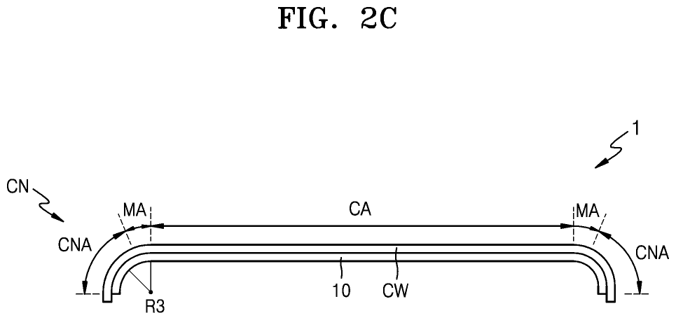

FIG. 1 is a schematic perspective view of an embodiment of a display apparatus 1. FIG. 2A is a cross-sectional view of the display apparatus 1 taken along line A-A′ of FIG. 1, FIG. 2B is a cross-sectional view of the display apparatus 1 taken along line B-B′ of FIG. 1, and FIG. 2C is a cross-sectional view of the display apparatus 1 taken along line C-C′ of FIG. 1.

Referring to FIGS. 1 and 2A to 2C, the display apparatus 1 may have an edge in a first direction and an edge in a second direction. The first direction and the second direction may cross each other. In an embodiment, the first direction and the second direction may make an acute angle with each other, for example. In another embodiment, the first direction and the second direction may make an obtuse angle with each other or cross each other at right angles. Hereinafter, a case in which the first direction and the second direction cross each other at right angles is mainly described in detail. In an embodiment, the first direction may be an x direction or a −x direction, and the second direction may be a y direction or a −y direction, for example.

In an embodiment, a corner CN at which an edge in the first direction (e.g., the x direction or the −x direction in FIG. 1), meets an edge in the second direction (e.g., the y direction or the −y direction in FIG. 1) may have a predetermined curvature.

The display apparatus 1 may include a cover window CW and a display panel 10. The cover window CW may protect the display panel 10. In an embodiment, the cover window CW may be arranged on the display panel 10. In an embodiment, the cover window CW may include a flexible window. The cover window CW may protect the display panel 10 by being easily bent according to an external force without cracks, etc. being generated. The cover window CW may include glass, sapphire, and plastic. The cover window CW may include ultra-thin glass (“UTG”) or colorless polyimide (“CPI”), for example. In an embodiment, the cover window CW may have a structure in which a flexible polymer layer is arranged on one surface of a glass substrate, or may include only a polymer layer.

The display panel 10 may be arranged below the cover window CW. Although not shown in the drawings, the display panel 10 may adhere to the cover window CW via a transparent adhesion member, such as an optically clear adhesive (“OCA”) film.

The display panel 10 may display an image. The display panel 10 may include a substrate 100 and a sub-pixel PX. The substrate 100 may include a center area CA, a first side area SA1, a second side area SA2, a corner area CNA, a middle area MA, and a peripheral area PA. In an embodiment, the shape of the substrate 100 may define the shape of the display apparatus 1.

The center area CA may be flat. In an embodiment, the display apparatus 1 may provide most of the image on the center area CA.

The first side area SA1 may be bent while being adjacent to the center area CA in the first direction (e.g., the x direction or the −x direction in FIG. 1). The first side area SA1 may be defined as an area in a cross-section (e.g., an x-z cross-section) in the first direction (e.g., the x direction or the −x direction), the area being bent from the center area CA. The first side area SA1 may extend in the second direction (e.g., the y direction or the −y direction). In other words, the first side area SA1 may not bend in a cross-section (e.g., a y-z cross-section) in the second direction (e.g., the y direction or the −y direction). The first side area SA1 may extend from the center area CA in the first direction (e.g., the x direction or the −x direction). FIG. 2A illustrates that the first side area SA1 extending from the center area CA in the x direction and being bent and the first side area SA1 extending from the center area CA in the −x direction and being bent may have the same curvature. However, in another embodiment, the first side area SA1 extending from the center area CA in the x direction and being bent and the first side area SA1 extending from the center area CA in the −x direction and being bent may have different curvatures from each other.

The second side area SA2 may be bent while being adjacent to the center area CA in the second direction (e.g., the y direction or the −y direction). The second side area SA2 may be defined as an area on the cross-section (e.g., the y-z cross-section) in the second direction (e.g., the y direction or the −y direction), the area being bent from the center area CA. The second side area SA2 may extend in the first direction (e.g., the x direction or the −x direction). The second side area SA2 may not bend on the cross-section (e.g., the x-z cross-section) orthogonal to the first direction (e.g., the x direction or the −x direction). FIG. 2B illustrates that the second side area SA2 extending from the center area CA in the y direction and being bent and the second side area SA2 extending from the center area CA in the −y direction and being bent may have the same curvature. However, in another embodiment, the second side area SA2 extending from the center area CA in the y direction and being bent and the second side area SA2 extending from the center area CA in the −y direction and being bent may have different curvatures from each other.

The corner area CNA may be an area arranged at the corner CN. In an embodiment, the corner area CNA may be an area at which an edge of the display apparatus 1 in the first direction (e.g., the x direction or the −x direction) and an edge of the display apparatus 1 in the second direction (e.g., the y direction or the −y direction) meet each other. In an embodiment, the corner area CNA may at least partially surround the center area CA, the first side area SA1, and the second side area SA2. In an alternative embodiment, the corner area CNA may at least partially surround the center area CA, the first side area SA1, the second side area SA2, and the middle area MA. When the first side area SA1 extends in the first direction (e.g., the x direction or the −x direction) and bends, and the second side area SA2 extends in the second direction (e.g., the y direction or the −y direction) and bends, at least a portion of the corner area CNA may extend in the first direction (e.g., the x direction or the −x direction) and may bend and may extend in the second direction (e.g., the y direction or the −y direction) and may bend. In other words, at least a portion of the corner area CNA may be a curved area having a plurality of curvatures in a plurality of directions. In an embodiment, a plurality of corner area CNA may be provided.

The middle area MA may be arranged between the center area CA and the corner area CNA. In an embodiment, the middle area MA may extend between the first side area SA1 and the corner area CNA. In an embodiment, the middle area MA may extend between the second side area SA2 and the corner area CNA. In an embodiment, the middle area MA may bend. A driving circuit for providing an electrical signal to the sub-pixel PX and/or power lines for providing power to the sub-pixel PX may be arranged in the middle area MA. In this case, the sub-pixel PX arranged in the middle area MA may overlap the driving circuit and/or the power lines. In some embodiments, the driving circuit and/or the power line arranged in the middle area MA may be omitted. In this case, the sub-pixel PX arranged in the middle area MA may not overlap the driving circuit and/or the power line.

The peripheral area PA may be arranged outside the center area CA. In an embodiment, the peripheral area PA may be arranged outside the first side area SA1. The peripheral area PA may extend from the first side area SA1. In an embodiment, the peripheral area PA may be arranged outside the second side area SA2. The peripheral area PA may extend from the second side area SA2. The sub-pixel PX may not be arranged in the peripheral area PA. Thus, the peripheral area PA may be a non-display area where an image is not displayed. A driving circuit for providing an electrical signal to the sub-pixel PX and/or power lines for providing power to the sub-pixel PX may be arranged in the peripheral area PA.

Referring to FIG. 2A, the first side area SA1, the middle area MA, and a portion of the corner area CNA may bend by a first radius of curvature R1. Referring to FIG. 2B, the second side area SA2, the middle area MA, and another portion of the corner area CNA may bend by a second radius of curvature R2. Referring to FIG. 2C, the middle area MA and yet another portion of the corner area CNA may bend by a third radius of curvature R3.

The sub-pixel PX may be arranged on the substrate 100. In an embodiment, the sub-pixel PX may be provided in a multiple number, and the plurality of sub-pixels PX may emit light to display an image. In an embodiment, each of the plurality of sub-pixels PX may include a red sub-pixel, a green sub-pixel, and a blue sub-pixel. In an alternative embodiment, each of the plurality of sub-pixels PX may include a red sub-pixel, a green sub-pixel, a blue sub-pixel, and a white sub-pixel, for example.

The sub-pixel PX may be arranged in at least one of the center area CA, the first side area SA1, the second side area SA2, and the corner area CNA. In an embodiment, the plurality of sub-pixels PX may be arranged in the center area CA, the first side area SA1, the second side area SA2, the corner area CNA, and the middle area MA. In this case, the display apparatus 1 may display an image in the center area CA, the first side area SA1, the second side area SA2, the corner area CNA, and the middle area MA. In an embodiment, the plurality of sub-pixels PX arranged in the center area CA, the first side area SA1, the second side area SA2, the corner area CNA, and the middle area MA may each provide an independent image. In another embodiment, the plurality of sub-pixels PX arranged in the center area CA, the first side area SA1, the second side area SA2, the corner area CNA, and the middle area MA may each provide a portion of any one image.

The display apparatus 1 may display images not only in the center area CA, but also in the first side area SA1, the second side area SA2, the middle area MA, and the corner area CNA. Thus, a ratio of a display area in the display apparatus 1, the display area corresponding to an area for displaying an image, may be increased. Also, because the display apparatus 1 may display an image by being bent at the corner CN, an aesthetic sense may be improved.

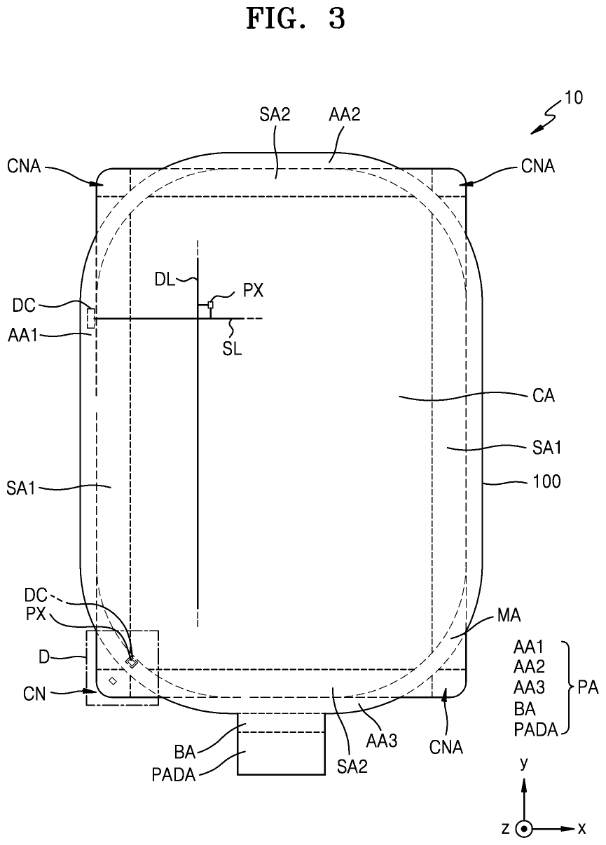

FIG. 3 is a schematic plan view of an embodiment of a display panel 10 that may be included in a display apparatus.

Referring to FIG. 3, the display panel 10 may include the substrate 100, the sub-pixel PX, and a driving circuit DC. The substrate 100 may include the center area CA, the first side area SA1, the second side area SA2, the corner area CNA, the middle area MA, and the peripheral area PA.

The peripheral area PA may be arranged outside the center area CA. The peripheral area PA may include a first adjacent area AA1, a second adjacent area AA2, a third adjacent area AA3, a bending area BA, and a pad area PADA.

The first adjacent area AA1 may be arranged outside the first side area SA1. In other words, the first side area SA1 may be arranged between the first adjacent area AA1 and the center area CA. The first adjacent area AA1 may extend from the first side area SA1. In an embodiment, the first adjacent area AA1 may extend from the first side area SA1 in the first direction (e.g., the x direction or the −x direction). In an embodiment, the driving circuit DC may be arranged in the first adjacent area AA1.

The second adjacent area AA2 and the third adjacent area AA3 may be arranged outside the second side area SA2. In other words, the second side area SA2 may be arranged between the second adjacent area AA2 and the center area CA. Also, the second side area SA2 may be arranged between the third adjacent area AA3 and the center area CA. The second and third adjacent areas AA2 and AA3 may extend from the second side area SA2. In an embodiment, the second adjacent area AA2 and the third adjacent area AA3 may extend in the second direction (e.g., the y direction or the −y direction). The center area CA may be arranged between the second adjacent area AA2 and the third adjacent area AA3.

The bending area BA may be arranged outside the third adjacent area AA3. In other words, the third adjacent area AA3 may be arranged between the bending area BA and the second side area SA2. The display panel 10 may be bent in the bending area BA. In this case, the pad area PADA may face a rear surface of the display panel 10 that is opposite to an upper surface of the display panel 10 that displays an image. Thus, an area of the peripheral area PA that is seen by a user may be reduced.

The pad area PADA may be arranged outside the bending area BA. In other words, the bending area BA may be arranged between the third adjacent area AA3 and the pad area PADA. A pad (not shown) may be arranged in the pad area PADA. The display panel 10 may receive an electrical signal and/or a power voltage through the pad.

At least one of the first side area SA1, the second side area SA2, the corner area CNA, and the middle area MA may be bent. In an embodiment, as described above, the first side area SA1 and a portion of the corner area CNA may bend in a cross-section (e.g., the x-z cross-section) in the first direction (e.g., the x direction or the −x direction), for example. The second side area SA2 and another portion of the corner area CNA may bend in a cross-section (e.g., the y-z cross-section) in the second direction (e.g., the y direction or the −y direction). Yet another portion of the corner area CNA may bend on the cross-section (e.g., the x-z cross-section) in the first direction (e.g., the x direction or the −x direction) and may bend on the cross-section (e.g., the y-z cross-section) in the second direction (e.g., the y direction or the −y direction).

When the corner area CNA is bent, the compressive strain occurring in the corner area CNA may be greater than the tensile strain occurring in the corner area CNA. In this case, it may be desired to implement the substrate 100 and a multi-layered structure on the substrate 100 that may be contracted in at least a portion of the corner area CNA. In an embodiment, a structure of the display panel 10 in the corner area CNA may be different from a structure of the display panel 10 in the center area CA.

The sub-pixel PX and the driving circuit DC may be arranged on the substrate 100. The sub-pixel PX may be arranged in at least one of the center area CA, the first side area SA1, the second side area SA2, the corner area CNA, and the middle area MA. The sub-pixel PX may include a display element. In an embodiment, the display element may include an organic light-emitting diode including an organic emission layer. In an alternative embodiment, the display element may include a light-emitting diode including an inorganic emission layer. A size of the light-emitting diode may be micro-scale or nano-scale. In an embodiment, the light-emitting diode may include a micro-light-emitting diode. In an alternative embodiment, the light-emitting diode may include a nanorod-light-emitting diode, for example. The nanorod-light-emitting diode may include GaN. In an embodiment, a color conversion layer may be arranged on the nanorod-light-emitting diode. The color conversion layer may include quantum dots. In an alternative embodiment, the display element may include a quantum dot light-emitting diode including a quantum dot emission layer.

The sub-pixel PX may include a plurality of sub-pixels, and each of the plurality of sub-pixels may emit a predetermined color of light by the display element. In this specification, a sub-pixel denotes a smallest unit for realizing an image, which corresponds to an emission area.

In an embodiment, the driving circuit DC may be a scan driving circuit configured to provide a scan signal to each sub-pixel PX through a scan line SL. In an alternative embodiment, the driving circuit DC may be a data driving circuit configured to provide a data signal to each sub-pixel PX through a data line DL. In an embodiment, the data driving circuit may be arranged in the third adjacent area AA3 or the pad area PADA. In an alternative embodiment, the data driving circuit may be arranged on a display circuit board connected to the pad of the pad area PADA.

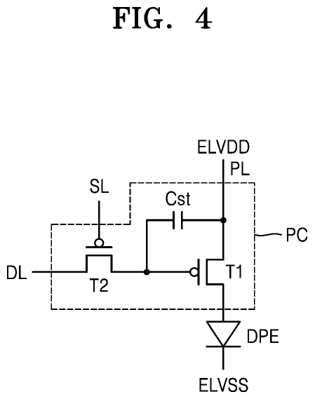

FIG. 4 is a schematic equivalent circuit diagram illustrating an embodiment of a display element and a sub-pixel circuit electrically connected thereto of a display apparatus.

Referring to FIG. 4, a sub-pixel circuit PC may be electrically connected to a display element DPE. The sub-pixel circuit PC may include a first thin-film transistor T1, a second thin-film transistor T2, and a storage capacitor Cst.

The second thin-film transistor T2 is a switching thin-film transistor, and may be connected to a scan line SL and a data line DL and may transmit a data signal or data voltage provided through the data line DL to the first thin-film transistor T1 in response to a scan signal or switching voltage provided through the scan line SL.

The storage capacitor Cst may be connected to the second thin-film transistor T2 and a driving voltage line PL and may store a voltage corresponding to a difference between a voltage received from the second thin-film transistor T2 and a driving voltage ELVDD supplied to the driving voltage line PL.

The first thin-film transistor T1 is a driving thin-film transistor, and may be connected to the driving voltage line PL and the storage capacitor Cst and may control a driving current flowing from the driving voltage line PL through the display element DPE, in correspondence with a value of the voltage stored in the storage capacitor Cst. The display element DPE may emit light having a predetermined brightness according to the driving current. A sub-pixel electrode (e.g., an anode) of the display element DPE may be connected to the sub-pixel circuit PC, and an opposite electrode (e.g., a cathode) of the display element DPE may receive a common voltage ELVSS.

FIG. 4A illustrates that the sub-pixel circuit PC includes two thin-film transistors and one storage capacitor. However, in another embodiment, the number of thin-film transistors or the number of storage capacitors may be variously changed according to the design of the sub-pixel circuit PC.

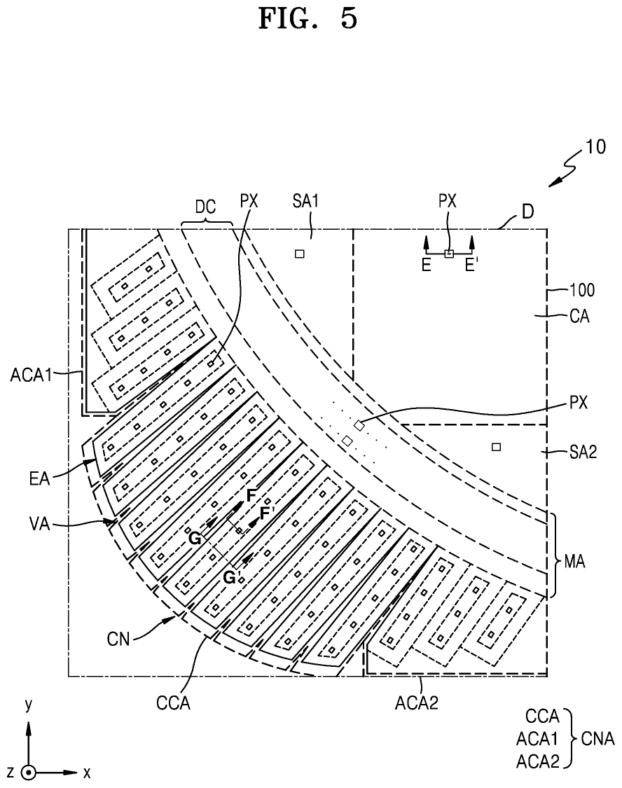

FIG. 5 is an enlarged view of a portion D of the display panel 10 of FIG. 3.

Referring to FIG. 5, the substrate 100 may include the center area CA, the first side area SA1, the second side area SA2, and the corner area CNA.

The corner area CNA may be an area at the corner CN of the display panel 10. The corner area CNA may include a center corner area CCA, a first adjacent corner area ACA1, and a second adjacent corner area ACA2.

The center corner area CCA may include an extension area EA. The extension area EA may extend in a direction away from the center area CA. A plurality of extension areas EA may be provided. Each of the plurality of extension areas EA may extend in a direction away from the center area CA. In an embodiment, the plurality of extension areas EA may extend in direction crossing the first direction (e.g., the x direction or the −x direction) and the second direction (e.g., the y direction or the −y direction), for example.

A separation area VA may be defined between adjacent extension areas EA. The separation area VA may be an area in which components of the display panel 10 are not arranged. When the center corner area CCA is bent at the corner CN, compressive strain greater than tensile strain may occur in the center corner area CCA. However, because the separation area VA is defined between the adjacent extension areas EA, the display panel 10 may be bent without being damaged in the center corner area CCA.

The first adjacent corner area ACA1 may be adjacent to the center corner area CCA. At least a portion of the first side area SA1 and the first adjacent corner area ACA1 may be disposed in the first direction (e.g., the x direction or the −x direction). An end of the first adjacent corner area ACA1 in a direction toward the center corner area CCA and an end of the center corner area CCA in a direction toward the first adjacent corner area ACA1 may be spaced apart from each other. The first adjacent corner area ACA1 may appear to be bent in a cross-section (the z-x cross-section) in the first direction and not bent in a cross-section (the y-z cross-section) in the second direction. The separation area VA may not be defined inside the first adjacent corner area ACA1.

The second adjacent corner area ACA2 may also be adjacent to the center corner area CCA. At least a portion of the second side area A2 and the second adjacent corner area ACA2 may be disposed in the second direction (the y direction or the −y direction). An end of the second adjacent corner area ACA2 in a direction toward the center corner area CCA and an end of the center corner area CCA in a direction toward the second adjacent corner area ACA2 may be spaced apart from each other. The second adjacent corner area ACA2 may appear to be not bent in a cross-section (the z-x cross-section) in the first direction and bent in a cross-section (the y-z cross-section) in the second direction. The separation area VA may not be defined inside the second adjacent corner area ACA2.

The middle area MA may be disposed between the center area CA and the corner area CNA. The middle area MA may extend between the center area CA and the first adjacent corner area ACA1. Also, the middle area MA may extend between the center area CA and the second adjacent corner area ACA2. The middle area MA may at least partially surround the center area CA, the first side area SA1, and the second side area SA2.

As shown in FIG. 5, a plurality of sub-pixels PX may be arranged in the center area CA, the first side area SA1, the second side area SA2, the corner area CNA, and the middle area MA. Accordingly, the display panel 10 may display images in the center area CA, the first side area SA1, the second side area SA2, the corner area CNA, and the middle area MA. The plurality of extension areas EA may include a plurality of sub-pixels PX. In each of the plurality of extension areas EA, a plurality of sub-pixels PX may be arranged in an extending direction of the extension area EA. Each of the sub-pixels PX may include a display element DPE (refer to FIG. 4).

In an embodiment, a driving circuit DC for providing an electrical signal to the sub-pixel PX and/or power lines for providing power to the sub-pixel PX may be arranged in the middle area MA. A plurality of driving circuits DC may be provided. The driving circuit DC may extend in a direction in which the middle area MA extends. The driving circuit DC may at least partially surround the center area CA, the first side area SA1, and the second side area SA2.

The sub-pixel PX arranged in the middle area MA may overlap the driving circuit DC and/or the power lines. In this case, the middle area MA may function as a display area even when the driving circuit DC and/or the power lines are arranged. However, the disclosure is not limited thereto. In an embodiment, the driving circuit DC and/or the power lines may not be arranged in the middle area MA, for example.

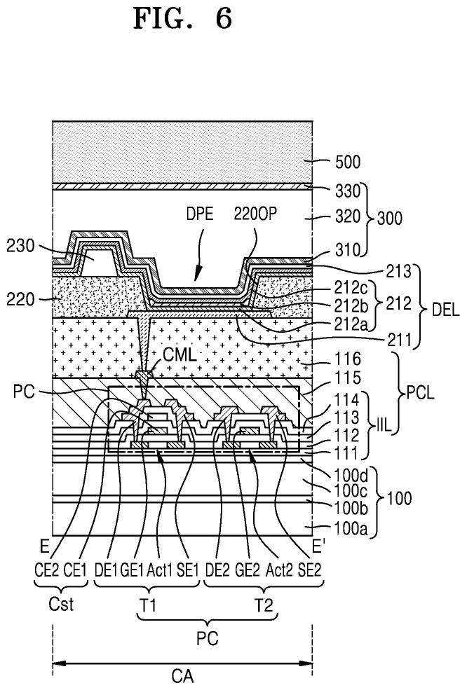

FIG. 6 is a schematic cross-sectional view of an embodiment of a display panel in an embodiment, and is a cross-sectional view of the display panel taken along line E-E′ of FIG. 5.

Referring to FIG. 5, the display panel 10 may include the substrate 100, a sub-pixel circuit layer PCL, a display element layer DEL, and an encapsulation layer 300.

The substrate 100 may include various materials, such as glass, metal, or organic materials. In another embodiment, the substrate 100 may include a flexible material. In an embodiment, the substrate 100 may include ultra-thin flexible glass (e.g., a thickness of several tens of micrometers to several hundred micrometers) or a polymer resin, for example. When the substrate 100 includes a polymer resin, the substrate 100 may include polyimide. In an alternative embodiment, the substrate 100 may include polyethersulfone, polyarylate, polyetherimide, polyethylene naphthalate, polyethylene terephthalate, polyphenylene sulfide, polycarbonate, cellulose tri acetate, or/and cellulose acetate propionate.

In an embodiment, the substrate 100 may include a first base layer 100a, a first barrier layer 100b, a second base layer 100c, and a second barrier layer 100d. In an embodiment, the first base layer 100a, the first barrier layer 100b, the second base layer 100c, and the second barrier layer 100d may be sequentially stacked. In an alternative embodiment, the substrate 100 may include glass.

At least one of the first base layer 100a and the second base layer 100c may include a polymer resin, such as polyethersulfone, polyarylate, polyether imide, polyethylene naphthalate, polyethylene terephthalate, polyphenylene sulfide, polyimide, polycarbonate, cellulose tri acetate, or cellulose acetate propionate.

The first barrier layer 100b and the second barrier layer 100d may prevent the penetration of external impurities and may include a single layer or layers including an inorganic material, such as silicon nitride, silicon oxide, and/or silicon oxynitride.

The sub-pixel circuit layer PCL may be arranged on the substrate 100. The sub-pixel circuit layer PCL may include the sub-pixel circuit PC. The sub-pixel circuit PC may be arranged on the center area CA. In an embodiment, the sub-pixel circuit PC may include at least one thin-film transistor. The sub-pixel circuit PC may include the first thin-film transistor T1, the second thin-film transistor T2, and the storage capacitor Cst.

The sub-pixel circuit layer PCL may further include an inorganic insulating layer IIL, a first insulating layer 115, and a second insulating layer 116 arranged below or/and above components of the first thin-film transistor T1. The inorganic insulating layer IIL may include a buffer layer 111, a first gate insulating layer 112, a second gate insulating layer 113, and an inter-insulating layer 114. The first thin-film transistor T1 may include a first semiconductor layer Act1, a first gate electrode GE1, a first source electrode SE1, and a first drain electrode DE1.

The buffer layer 111 may be arranged on the substrate 100. The buffer layer 111 may include an inorganic insulating material, such as silicon nitride, silicon oxide, and silicon oxynitride, and may include a single layer or layers including the inorganic insulating material described above.

The first semiconductor layer Act1 may be arranged on the buffer layer 111. The first semiconductor layer Act1 may include polysilicon. In an alternative embodiment, the first semiconductor layer Act1 may include amorphous silicon, an oxide semiconductor, or an organic semiconductor. The first semiconductor layer Act1 may include a channel area, a drain area and a source area arranged at opposite sides of the channel area, respectively.

The first gate electrode GE1 may overlap the channel area. The first gate electrode GE1 may include a low-resistance metal material. The first gate electrode GE1 may include a conductive material including Mo, Al, Cu, Ti, etc. and may include layers or a single layer including the conductive material described above.

The first gate insulating layer 112 may be arranged between the first semiconductor layer Act1 and the first gate electrode GE1. The first gate insulating layer 112 may include an inorganic insulating material, such as silicon oxide, silicon nitride, silicon oxynitride, aluminum oxide, titanium oxide, tantalum oxide, hafnium oxide, and/or zinc oxide. In an embodiment, zinc oxide (ZnOₓ) may include ZnO and/or ZnO₂.

The second gate insulating layer 113 may cover the first gate electrode GE1. The second gate insulating layer 113 may include an inorganic insulating material, such as silicon oxide, silicon nitride, silicon oxynitride, aluminum oxide, titanium oxide, tantalum oxide, hafnium oxide, and/or zinc oxide, similar to the first gate insulating layer 112. In an embodiment, zinc oxide (ZnOₓ) may include ZnO and/or ZnO₂.

An upper electrode CE2 of the storage capacitor Cst may be arranged above the second gate insulating layer 113. The upper electrode CE2 may overlap the first gate electrode GE1 therebelow. In this case, the storage capacitor Cst may include the first gate electrode GE1 of the first thin-film transistor T1 and the upper electrode CE2, the first gate electrode GE1 and the upper electrode CE2 overlapping each other with the second gate insulating layer 113 therebetween. That is, the first gate electrode GE1 of the first thin-film transistor T1 may function as a lower electrode CE1 of the storage capacitor Cst. In other words, the storage capacitor Cst and the first thin-film transistor T1 may overlap each other. In some embodiments, the storage capacitor Cst may not overlap the first thin-film transistor T1. The upper electrode CE2 may include Al, Pt, Pd, Ag, Mg, Au, Ni, Nd, Ir, Cr, Ca, Mo, Ti, W, and/or Cu and may include a single layer or layers including the materials described above.

The inter-insulating layer 114 may cover the upper electrode CE2. The inter-insulating layer 114 may include silicon oxide, silicon nitride, silicon oxynitride, aluminum oxide, titanium oxide, tantalum oxide, hafnium oxide, zinc oxide, or the like. In an embodiment, zinc oxide (ZnOₓ) may include ZnO and/or ZnO₂. The inter-insulating layer 114 may include a single layer or layers including the inorganic insulating materials described above.

Each of the first drain electrode DE1 and the first source electrode SE1 may be arranged on the inter-insulating layer 114. The first drain electrode DE1 and the first source electrode SE1 may include a highly conductive material. The first drain electrode DE1 and the first source electrode SE1 may include a conductive material including Mo, Al, Cu, Ti, etc. and may include layers or a single layer including the materials described above. In an embodiment, the first drain electrode DE1 and the first source electrode SE1 may have a multi-layered structure including Ti/Al/Ti layers.

The second thin-film transistor T2 may include a second semiconductor layer Act2, a second gate electrode GE2, a second drain electrode DE2, and a second source electrode SE2. The second semiconductor layer Act2, the second gate electrode GE2, the second drain electrode DE2, and the second source electrode SE2 are similar to the first semiconductor layer Act1, the first gate electrode GE1, the first drain electrode DE1, and the first source electrode SE1, respectively, and thus, detailed descriptions thereof are omitted.

The first insulating layer 115 may be arranged on at least one thin-film transistor. In an embodiment, the first insulating layer 115 may be arranged to cover the first drain electrode DE1 and the first source electrode SE1. In an embodiment, the first insulating layer 115 may include an organic material. In an embodiment, the first insulating layer 115 may include an organic insulating material, such as a general-purpose polymer such as polymethylmethacrylate (“PMMA”) or polystyrene (“PS”), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or any combinations thereof, for example.

A connection electrode CML may be arranged on the first insulating layer 115. In this case, the connection electrode CML may be connected to the first drain electrode DE1 or the first source electrode SE1 through a contact hole of the first insulating layer 115. The connection electrode CML may include a highly conductive material. The connection electrode CML may include a conductive material including Mo, Al, Cu, Ti, etc. and may include layers or a single layer including the conductive materials described above. In an embodiment, the connection electrode CML may have a multi-layered structure including Ti/Al/Ti layers.

The second insulating layer 116 may be arranged to cover the connection electrode CML and the first insulating layer 115. The second insulating layer 116 may include an organic material. The second insulating layer 116 may include an organic insulating material, such as a general-purpose polymer such as PMMA or PS, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or any combinations thereof.

The display element layer DEL may be arranged on the sub-pixel circuit layer PCL. The display element layer DEL may include the display element DPE, a bank layer 220, and a spacer 230. The display element DPE may include an organic light-emitting diode. The display element DPE may be electrically connected to the connection electrode CML through a contact hole of the second insulating layer 116. The display element DPE may include a sub-pixel electrode 211, an intermediate layer 212, and an opposite electrode 213.

The sub-pixel electrode 211 may be arranged on the second insulating layer 116. The sub-pixel electrode 211 may be electrically connected to the connection electrode CML through the contact hole of the second insulating layer 116. The sub-pixel electrode 211 may include a conductive oxide, such as indium tin oxide (“ITO”), indium zinc oxide (“IZO”), ZnO, indium oxide (In₂O₃), indium gallium oxide (“IGO”), or aluminum zinc oxide (“AZO”). In another embodiment, the sub-pixel electrode 211 may include a reflective layer including Ag, Mg, Al, Pt, Pd, Au, Ni, Nd, Ir, Cr, or any combinations thereof. In another embodiment, the sub-pixel electrode 211 may further include a layer including ITO, IZO, ZnO, or In₂O₃, above/below the reflective layer described above.

A bank layer 220 in which an opening 220OP exposing a central portion of the sub-pixel electrode 211 is defined may be arranged on the sub-pixel electrode 211. The opening 220OP of the bank layer 220 may define an emission area of light emitted from the display element DPE including an organic light-emitting diode. In an embodiment, a width of the opening 220OP of the bank layer 220 may correspond to a width of the emission area, for example. Also, the width of the opening 220OP of the bank layer 220 may correspond to a width of a sub-pixel.

In an embodiment, the bank layer 220 may include an organic insulating material. In another embodiment, the bank layer 220 may include an inorganic insulating material, such as silicon nitride, silicon oxynitride, or silicon oxide. In another embodiment, the bank layer 220 may include an organic insulating material and an inorganic insulating material. In some embodiments, the bank layer 220 may include a light-blocking material and may be provided in a black color. The light-blocking material may include a resin or paste including carbon black, a carbon nano-tube, and a black dye, a metal particle, such as Ni, Al, Mo, or any alloys thereof, a metal oxide particle (e.g., chromium oxide), a metal nitride particle (e.g., chromium nitride), or the like. When the bank layer 220 includes a light-blocking material, reflection of external light due to metal structures arranged below the bank layer 220 may be reduced.

The spacer 230 may be arranged on the bank layer 220. The spacer 230 may be provided to prevent the substrate 100 and/or the layers on the substrate 100 from being damaged in the process of manufacturing a display apparatus. In the process of manufacturing a display panel, a mask sheet may be used. In this case, the mask sheet may be introduced into the opening 220OP of the bank layer 220 or may adhere to the bank layer 220. The spacer 230 may prevent the substrate 100 and portions of the layers from being damaged or fractured due to a mask sheet when a deposition material is deposited on the substrate 100.

The spacer 230 may include an organic material such as polyimide. In an alternative embodiment, the spacer 230 may include an inorganic insulating material, such as silicon nitride or silicon oxide, or may include an organic insulating material and an inorganic insulating material. In an embodiment, the spacer 230 may include a different material from the bank layer 220. In an alternative embodiment, in another embodiment, the spacer 230 may include the same material as that of the bank layer 220, and in this case, the bank layer 220 and the spacer 230 may be formed together by a mask process using a halftone mask, etc.

The intermediate layer 212 may be arranged on the bank layer 220. The intermediate layer 212 may include an emission layer 212b arranged to correspond to the opening 220OP of the bank layer 220. The emission layer 212b may include a high molecular-weight or low molecular-weight organic material emitting a predetermined color of light.

The intermediate layer 212 may further include at least one of a first functional layer 212a between the sub-pixel electrode 211 and the emission layer 212b and a second functional layer 212c between the emission layer 212b and the opposite electrode 213. In an embodiment, the first functional layer 212a and the second functional layer 212c may be arranged below and above the emission layer 212b, respectively. The first functional layer 212a may include a hole transport layer (“HTL”), or an HTL and a hole injection layer (“HIL”), for example. The second functional layer 212c may include an electron transport layer (“ETL”) and/or an electron injection layer (“EIL”). The first functional layer 212a and/or the second functional layer 212c may be a common layer formed to cover an entirety of the substrate 100, like the opposite electrode 213 to be described below.

The opposite electrode 213 may be arranged on the intermediate layer 212. The opposite electrode 213 may include a conductive material having a relatively low work function. In an embodiment, the opposite electrode 213 may include a (semi) transparent layer including Ag, Mg, Al, Pt, Pd, Au, Ni, Nd, Ir, Cr, Li, Ca, or any alloys thereof, for example. In an alternative embodiment, the opposite electrode 213 may further include a layer including ITO, IZO, ZnO, or In₂O₃ on the (semi) transparent layer including the materials described above.

In some embodiments, a capping layer may be further arranged on the opposite electrode 213. The capping layer may include an inorganic insulating material, such as silicon nitride, and/or an organic insulating material. When the capping layer includes an organic insulating material, the capping layer may include an organic insulating material, e.g., a triamine derivative, a carbazole biphenyl derivative, an arylenediamine derivative, an aluminum kinolium composite (Alq3), acrylic, polyimide, or polyamide.

The encapsulation layer 300 may be arranged on the opposite electrode 213. Also, when the capping layer is arranged, the encapsulation layer 300 may be arranged on the capping layer. In an embodiment, the encapsulation layer 300 may include at least one inorganic encapsulation layer and at least one organic encapsulation layer. In an embodiment, the encapsulation layer 300 may include a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include one or more inorganic materials from among aluminum oxide, titanium oxide, tantalum oxide, hafnium oxide, zinc oxide, silicon oxide, silicon nitride, and silicon oxynitride. In an embodiment, zinc oxide (ZnOₓ) may include ZnO and/or ZnO₂. The organic encapsulation layer 320 may include a polymer-based material. The polymer-based material may include acryl-based resins, epoxy-based resins, polyimide, polyethylene, etc. In an embodiment, the organic encapsulation layer 320 may include acrylate.

A resin layer 500 may be arranged on the display panel 10. The resin layer 500 may be arranged to cover the encapsulation layer 300. The resin layer 500 may be arranged between the display panel 10 and the cover window CW (refer to FIGS. 2A to 2C). The resin layer 500 may be arranged to cover the entirety of the surface of the display panel 10. As described below, the resin layer 500 may have a relatively high modulus. The resin layer 500 may reinforce the rigidity of the display panel 10.

Although not shown in the drawings, a touch sensor layer may be further arranged between the encapsulation layer 300 and the resin layer 500. The touch sensor layer may obtain coordinate information according to an external input, e.g., a touch event. The touch sensor layer may include a sensing electrode (or touch electrode) and signal lines (trace lines) connected to the sensing electrode. The touch sensor layer may sense an external input by a mutual capacitance method or/and a self-capacitance method.

A reflection prevention layer may be further arranged on the touch sensor layer. The reflection prevention layer may reduce the reflectivity of light that is incident toward the display panel 10. In an embodiment, the reflection prevention layer may include a phase retarder and a polarizer. The phase retarder may include a film-type phase retarder or a liquid crystal coating-type phase retarder, and may include a λ/2 phase retarder and/or a λ/4 phase retarder. The polarizer may also include a film-type polarizer or a liquid crystal coating-type polarizer. The film-type polarizer may include an elongation-type synthetic resin film, and the liquid crystal coating-type polarizer may include liquid crystals arranged in a predetermined shape. The phase retarder and the polarizer may further include a protective film.

In an alternative embodiment, the reflection prevention layer may include a black matrix and color filters. The color filters may be arranged by taking into account a color of light emitted from each of the plurality of display elements DPE in the display panel 10. Each of the color filters may include a red, green, or blue pigment or dye. In an alternative embodiment, each of the color filters may further include quantum dots, in addition to the pigment or the dye described above. In an alternative embodiment, some of the color filters may not include the pigment or the dye described above and may include scattered particles, such as oxide titanium.

In an alternative embodiment, the reflection prevention layer may include a destructive interference structure. The destructive interference structure may include a first reflective layer and a second reflective layer arranged in different layers from each other. First reflective light and second reflective light reflected from the first reflective layer and the second reflective layer, respectively, may destructively interfere, and thus, the reflectivity of external light may be decreased.

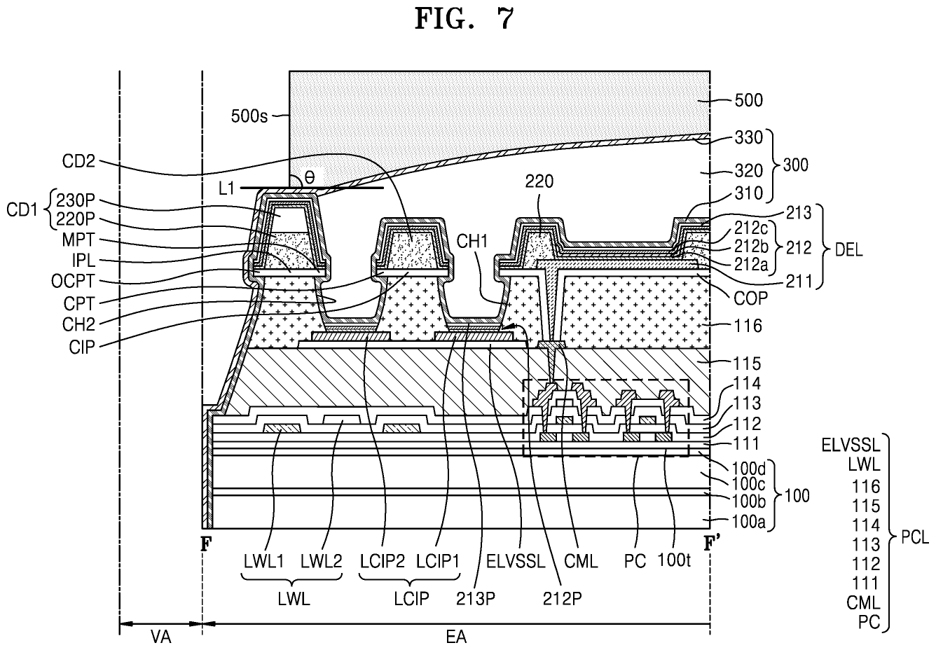

FIG. 7 is a schematic cross-sectional view of an embodiment of a display panel in an embodiment, taken along line F-F′ of FIG. 5.

Although a sub-pixel PX disposed in the center area CA has been previously described with reference to FIG. 6, the structure of the extension area EA adjacent to the separation area VA and a sub-pixel PX disposed in the extension area EA will be described with reference to FIG. 7.

Referring to FIG. 7, the sub-pixel circuit layer PCL may include a sub-pixel circuit PC, a buffer layer 111, a first gate insulating layer 112, a second gate insulating layer 113, an inter-insulating layer 114, a first insulating layer 115, a second insulating layer 116, and a connection electrode CML. The sub-pixel circuit layer PCL may further include a lower wiring line LWL and a power supply line ELVSSL.

The lower wiring line LWL may transmit a power voltage and/or an electrical signal to a sub-pixel arranged in the corner area CNA. The lower wiring line LWL may include a first lower wiring line LWL1 and a second lower wiring line LWL2. The first lower wiring line LWL1 may be between the first gate insulating layer 112 and the second gate insulating layer 113, and the second lower wiring line LWL2 may be between the second gate insulating layer 113 and the inter-insulating layer 114.

The power supply line ELVSSL may be arranged on the first insulating layer 115 like the connection electrode CML, and may include the same material as that of the connection electrode CML and may be formed simultaneously with the connection electrode CML. The power supply line ELVSSL may be electrically connected to the opposite electrode 213 included in the organic light-emitting diode, which is the display element DPE, and may apply an electrical signal to the opposite electrode 213.

The second insulating layer 116 may cover the power supply line ELVSSL and the connection electrode CML. As shown in FIG. 7, a first corner hole CH1 and a second corner hole CH2 may be defined in the second insulating layer 116. A contact hole may be defined in the second insulating layer 116. The sub-pixel electrode 211 disposed on the second insulating layer 116 may be connected to the connection electrode CML through the contact hole. The first corner hole CH1, the second corner hole CH2, and the contact hole may be defined at the same time.

The first corner hole CH1 and the second corner hole CH2 may overlap the power supply line ELVSSL. A lower corner inorganic pattern LCIP disposed on the power supply line ELVSSL may prevent or reduce damage to the power supply line ELVSSL in the process of forming the first corner hole CH1 and the second corner hole CH2. Specifically, the lower corner inorganic pattern LCIP may include a first lower corner inorganic pattern LCIP1 and a second lower corner inorganic pattern LCIP2, and the first lower corner inorganic pattern LCIP1 may overlap the first corner hole CH1 and the second lower corner inorganic pattern LCIP2 may overlap the second corner hole CH2. In the process of forming the first corner hole CH1 and the second corner hole CH2, the lower corner inorganic pattern LCIP may prevent or reduce the exposure of the power supply line ELVSSL, thereby preventing or reducing damage to the power supply line ELVSSL. The lower corner inorganic pattern LCIP may include silicon oxide, silicon nitride, silicon oxynitride, aluminum oxide, titanium oxide, tantalum oxide, hafnium oxide, zinc oxide, or the like. In an embodiment, zinc oxide (ZnOₓ) may include ZnO and/or ZnO₂.

An overlapping inorganic pattern COP, a corner inorganic pattern CIP, and an inorganic pattern line IPL may be disposed on the second insulating layer 116. The overlapping inorganic pattern COP, the corner inorganic pattern CIP, and the inorganic pattern line IPL may include the same material and may be formed at the same time. The overlapping inorganic pattern COP, the corner inorganic pattern CIP, and the inorganic pattern line IPL may include silicon oxide, silicon nitride, silicon oxynitride, aluminum oxide, titanium oxide, tantalum oxide, hafnium oxide, zinc oxide, or the like. In an embodiment, zinc oxide (ZnOₓ) may include ZnO and/or ZnO₂.

The overlapping inorganic pattern COP may be disposed on the second insulating layer 116 and may be disposed near a contact hole. As shown in FIG. 7, the overlapping inorganic pattern COP may also be disposed on the inner surface of the contact hole. In this case, the sub-pixel electrode 211 disposed on the second insulating layer 116 may be disposed on the overlapping inorganic pattern COP and connected to the connection electrode CML through a contact hole.

The corner inorganic pattern CIP may be spaced apart from the overlapping inorganic pattern COP by the first corner hole CH1. The corner inorganic pattern CIP may have a shape that at least partially surrounds the overlapping inorganic pattern COP in a plan view. The inorganic pattern line IPL may be spaced apart from the corner inorganic pattern CIP by the second corner hole CH2. The inorganic pattern line IPL may have a shape that at least partially surrounds the corner inorganic pattern CIP in a plan view.

The corner inorganic pattern CIP may have a corner protruding tip CPT protruding toward the center of at least one of the first corner hole CH1 and the second corner hole CH2. FIG. 7 shows that the corner inorganic pattern CIP protrudes toward the center of each of the first corner hole CH1 and the second corner hole CH2. The inorganic pattern line IPL may have an intermediate protruding tip MPT protruding toward the center of the second corner hole CH2. In addition, the inorganic pattern line IPL may have an outer corner protruding tip OCPT protruding toward the separation area VA. As shown in FIG. 7, the overlapping inorganic pattern COP may also have a protruding tip protruding toward the center of the first corner hole CH1.

A corner dam may be arranged in the extension area EA. In an embodiment, a first corner dam CD1 and a second corner dam CD2 spaced apart from each other may be arranged in the extension area EA. The first corner dam CD1 may be arranged between the separation area VA and the second corner dam CD2. FIG. 7 shows two corner dams, but the disclosure is not limited thereto. In an embodiment, one corner dam may be provided or three or more corner dams may be provided, for example.

In an embodiment, the first corner dam CD1 may include a first pattern 220P and a second pattern 230P. The first pattern 220P may be arranged on the inorganic pattern line IPL. The first pattern 220P may be formed simultaneously with the bank layer 220, and may include the same material as that of the bank layer 220. The first pattern 220P may be disposed on the inorganic pattern line IPL. The second pattern 230P may be arranged on the first pattern 220P. The second pattern 230P may be formed simultaneously with the spacer 230, and may include the same material as that of the spacer 230. In this case, the first pattern 220P and the second pattern 230P may form the first corner dam CD1 together with the inorganic pattern line IPL. In an embodiment, the second corner dam CD2 may be disposed on the corner inorganic pattern CIP. The second corner dam CD2 may be formed simultaneously with the bank layer 220, and may include the same material as that of the bank layer 220. However, the disclosure is not limited thereto. The structures of the first corner dam CD1 and the second corner dam CD2 may vary depending on the design. In an embodiment, the second pattern 230P may be omitted from the first corner dam CD1, for example.

An intermediate layer 212 may be arranged on the bank layer 220. The intermediate layer 212 may include an emission layer 212b arranged in an opening of the bank layer 220 and overlapping the sub-pixel electrode 211. The intermediate layer 212 may further include at least one of a first functional layer 212a disposed between the sub-pixel electrode 211 and the emission layer 212b and a second functional layer 212c disposed on the emission layer 212b.

As described above, the overlapping inorganic pattern COP may have a protruding tip protruding toward the center of the first corner hole CH1. The corner inorganic pattern CIP may have a corner protruding tip CPT protruding toward the center of the first corner hole CH1. Accordingly, when the first functional layer 212a and the second functional layer 212c are formed, a functional layer pattern 212P, which is separated from the first functional layer 212a and the second functional layer 212c by the protruding tip of the overlapping inorganic pattern COP and the corner protruding tip CPT of the corner inorganic pattern CIP and is disposed in the first corner hole CH1, may be formed. In addition, the inorganic pattern line IPL may have an intermediate protruding tip MPT protruding toward the center of the second corner hole CH2. Accordingly, when the first functional layer 212a and the second functional layer 212c are formed, a functional layer pattern 212P disposed in the second corner hole CH2 may be defined by the corner protruding tip CPT and the intermediate protruding tip MPT.

The opposite electrode 213 is formed on the bank layer 220 and the intermediate layer 212 to correspond to a plurality of sub-pixel electrodes 211. According to the same principle as the formation of the functional layer pattern 212P disposed in the first corner hole CH1 and the second corner hole CH2, a common electrode pattern 213P disposed in the first corner hole CH1 and the second corner hole CH2 may be defined. A first inorganic encapsulation layer 310 may be disposed on the opposite electrode 213. The first inorganic encapsulation layer 310 may directly contact the protruding tip of the overlapping inorganic pattern COP, the corner protruding tip CPT of the corner inorganic pattern CIP, and the intermediate protruding tip MPT of the inorganic pattern line IPL. In some cases, the first inorganic encapsulation layer 310 may contact the common electrode pattern 213P in the first corner hole CH1 and the second corner hole CH2, and may cover inner surfaces of the first corner hole CH1 and the second corner hole CH2.

In an embodiment, the organic encapsulation layer 320 may be disposed on the first inorganic encapsulation layer 310 and may fill the first corner hole CH1 and the second corner hole CH2. The first corner dam CD1 may prevent a material for forming the organic encapsulation layer 320 from flowing outward during a manufacturing process. The second inorganic encapsulation layer 330 may be disposed on the organic encapsulation layer 320. In an embodiment, the second inorganic encapsulation layer 330 may directly contact the first inorganic encapsulation layer 310 on the first corner dam CD1.

A resin layer 500 may be arranged on the encapsulation layer 300. Specifically, the resin layer 500 may be arranged to cover the encapsulation layer 300 in the extension area EA. The resin layer 500 may contact the upper surface of the first corner dam CD1 in the extension area EA. In the extension area EA, the side surface 500s of the resin layer 500 may have an angle 0 of about 80 degrees to about 100 degrees with respect to the upper surface 100t of the substrate 100. In an embodiment, the side surface 500s of the resin layer 500 in the extension area EA may be perpendicular to the upper surface 100t of the substrate 100. In different expression, the angle θ formed by an imaginary straight line L1 parallel to the upper surface 100t of the substrate 100 and the side surface 500s of the resin layer 500 in the extension area EA may be about 80 degrees to about 100 degrees.

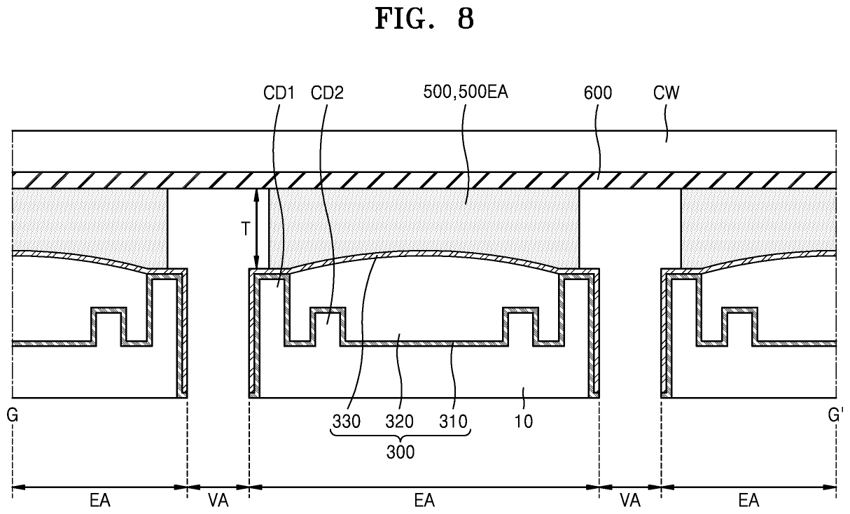

FIG. 8 is a schematic cross-sectional view illustrating an embodiment of a display panel in an embodiment and layers arranged on the display panel, and is a cross-sectional view taken along line G-G′ of FIG. 5.

Referring to FIGS. 5 and 8, the display panel 10 may include an extension area EA and a separation area VA. The display panel 10 may include one first corner dam CD1 at each of opposite ends of the extension area EA in a width direction thereof. In an embodiment, the first corner dam CD1 may be arranged to extend along the circumference of the extension area EA. Also, the display panel 10 may include one second corner dam CD2 at each of opposite ends of the extension area EA in the width direction thereof. In an embodiment, the second corner dam CD2 may be arranged to extend along the circumference of the extension area EA. Also, in an embodiment, the second corner dam CD2 may be arranged inside the first corner dam CD1 in the width direction of the extension area EA. In other words, the first corner dam CD1 may be arranged to surround the second corner dam CD2.

In an embodiment, the encapsulation layer 300, specifically, the organic encapsulation layer 320 may be arranged between two first corner dams CD1. The first inorganic encapsulation layer 310 may be arranged under the organic encapsulation layer 320 and cover the side surface of the display panel 10 beyond the second corner dam CD2 and the first corner dam CD1. The second inorganic encapsulation layer 330 may be arranged on the organic encapsulation layer 320 and cover the side surface of the display panel 10 beyond the second corner dam CD2 and the first corner dam CD1.

When a stacked structure including the display panel 10 is bent, portions of the stacked structure may receive compressive stress or tensile stress depending on where they are stacked. In the stacked structure, a neutral plane may exist at a position where compressive stress and tensile stress become zero. When the stacked structure including the display panel 10 is bent, compressive stress may be applied to the inside of the stacked structure with respect to the neutral plane, and tensile stress may be applied to the outside of the stacked structure. The further away from the neutral plane, the greater compressive or tensile stress may be applied to a portion of the stacked structure. The resin layer 500 may be arranged on the display panel 10 to move the position of the neutral plane in the stacked structure.

Stress applied to the display panel 10 may be controlled by appropriately adjusting the thickness and/or the modulus of the resin layer 500. Specifically, as the resin layer 500 is arranged on the display panel 10, the neutral plane may be moved upward to be adjacent to the encapsulation layer 300, particularly the second inorganic encapsulation layer 330. Accordingly, stress applied to the display panel 10, particularly the second inorganic encapsulation layer 330, may be reduced or eliminated. Cracks that may occur in the display panel 10, particularly in the second inorganic encapsulation layer 330, may be prevented in the bending extension area EA.

The resin layer 500 may be arranged to cover the encapsulation layer 300 in the extension area EA. The resin layer 500 may contact the upper surface of the first corner dam CD1 disposed at each of opposite ends of the extension area EA in the width direction thereof. The resin layer 500 may be arranged on the encapsulation layer 300 to reinforce the rigidity of the display panel 10. To this end, in an embodiment, the resin layer 500 may have a relatively high modulus. In an embodiment, the modulus of the resin layer 500 may be about 0.5 gigapascal (GPa) to about 3 GPa, preferably about 0.7 GPa to about 1.5 GPa. In an embodiment, the modulus of the resin layer 500 may be about 0.9 GPa.

In an embodiment, a thickness T of the resin layer 500 may be about 100 micrometers (μm) to about 200 μm, preferably about 130 μm to about 170 μm. In an embodiment, the thickness T of the resin layer 500 may be about 150 μm. In the specification, the thickness T of the resin layer 500 may refer to an average thickness of the resin layer 500 on the display panel 10.

In an embodiment, the resin layer 500 may include a resin composition. The resin layer 500 may be a cured product of a resin composition. As described below, the resin layer 500 may be formed by applying a resin composition and then curing the resin composition by irradiating light. The resin layer 500 may be patterned through exposure and development processes.

In an embodiment, the resin composition may include a solid content of 90% or more. In an embodiment, the resin composition may include 100% solid content without including a separate solvent, for example.

In an embodiment, the resin composition may include an acrylate oligomer, a monomer, and a photoinitiator. In an embodiment, the acrylate oligomer may include a urethane acrylate oligomer, an epoxy acrylate oligomer or a combination thereof. In an embodiment, the monomer may include a polyfunctional acrylate monomer, a low molecular weight ethylene glycol monomer, a bisphenol monomer, a photoinitiator or any combinations thereof. In addition, the resin composition may further include an additive.

In an embodiment, the resin composition may include about 10 weight percent (wt %) to about 30 wt % of an acrylate oligomer, about 55 wt % to about 85 wt % of a monomer, and about 3 wt % to about 5 wt % of a photoinitiator.

In an embodiment, the resin composition may include about 5 wt % to about 15 wt % of a urethane acrylate oligomer, about 5 wt % to about 15 wt % of an epoxy acrylate oligomer, about 20 wt % to about 35 wt % of a polyfunctional acrylate monomer, about 20 wt % to about 25 wt % of a bisphenol monomer, about 15 wt % to about 25 wt % of a low molecular weight ethylene glycol monomer, and about 3 wt % to about 5 wt % of a photoinitiator.

In the specification, the content of each component included in the resin composition may be based on the total weight of the components in the resin composition.

The acrylate oligomer may be a main component that controls overall physical properties of the resin composition constituting the resin layer 500. The acrylate oligomer may include a urethane acrylate oligomer and an epoxy acrylate oligomer. The urethane acrylate oligomer may increase flexibility of the resin layer 500 and the epoxy acrylate oligomer may increase rigidity of the resin layer 500.

The urethane acrylate oligomer may be included in the resin composition to have about 5 wt % to about 15 wt %, preferably about 8 wt % to about 12 wt %. The epoxy acrylate oligomer may be included in the resin composition to have about 5 wt % to about 15 wt %, preferably about 8 wt % to about 12 wt %. The mixing ratio of the urethane acrylate oligomer and the epoxy acrylate oligomer may be 1:3 to 3:1. As the resin composition includes the urethane acrylate oligomer and the epoxy acrylate oligomer satisfying the above ranges, an effect of increasing the modulus of the resin layer 500 may be obtained and brittleness may not occur.

The polyfunctional acrylate monomer may have 3 or 4 functional groups. In an embodiment, the polyfunctional acrylate monomer may include pentaerythritol tetraacrylate (“PETRA”), for example. The polyfunctional acrylate monomer may be included in the resin composition to have about 20 wt % to about 35 wt %, preferably about 25 wt % to about 30 wt %. In the case of using an acrylate monomer having functional groups exceeding the above numbers, the viscosity of the resin composition is relatively high and the shrinkage rate thereof is relatively high during curing, and thus, adhesion of the resin layer 500 may decrease and brittleness may occur. In the case of using an acrylate monomer having fewer functional groups than the above numbers, the resin layer 500 may have a relatively low thickness due to relatively low viscosity of the resin composition. When the acrylate monomer having the above numbers of functional groups is included within the above range, the thickness of the resin layer 500 may be formed relatively high by adjusting the viscosity of the resin composition. In addition, an effect of increasing the modulus of the resin layer 500 may be obtained and a brittle phenomenon may not occur.

The bisphenol monomer may be a component that improves surface hardness of the resin layer 500 and increases chemical resistance of the resin layer 500. The bisphenol monomer may be, e.g., bisphenol A diacrylate. The bisphenol monomer may be included in the resin composition to have about 20 wt % to about 25 wt %, preferably about 21.5 wt % to about 23.5 wt %.

The low molecular weight ethylene glycol monomer may be a component that dilutes the viscosity of the resin composition and controls the adhesion, flexibility, and toughness of the resin layer 500. The low molecular weight ethylene glycol monomer may include ethylene glycol diacrylate, for example. The low molecular weight ethylene glycol monomer may be included in the resin composition to have about 15 wt % to about 25 wt %, preferably about 17 wt % to about 23 wt %.

The photoinitiator may include 2,4,6-trimethylbenzoyl-diphenyl phosphine oxide (“TPO”) and hydroxy-cyclohexyl-phenyl ketone (Ciba Geigy's Irgacure 184®), for example. In an embodiment, the photoinitiator may be included in the resin composition to have about 3 wt % to about 5 wt %.

The additive may include at least one of a surface curing agent, a leveling agent, an adhesion promoter, and a release agent. In an embodiment, the additive may be included in the resin composition to have about 2 wt % to about 5 wt %.

The resin composition in an embodiment may include 10 wt % of urethane acrylate oligomer, 10 wt % of epoxy acrylate oligomer, 27.5 wt % of PETRA, 22.5 wt % of bisphenol A diacrylate, 4 wt % of photoinitiator (i.e., TPO and hydroxy-cyclohexyl-phenyl ketone (Ciba Geigy's Irgacure 184®)), and 3.5 wt % of additive.

In an embodiment, the resin composition may have a viscosity of about 900 centipoise (cp) to about 1100 cp at a temperature of 25 degrees Celsius (° C.).

The resin layer 500 may include a transparent material and be formed transparently. Therefore, in an exposure process of forming the resin layer 500, light may easily reach from the top to the bottom of the resin layer 500. In addition, the resin layer 500 is arranged on the display element DPE (refer to FIG. 6), and light emitted from the display element DPE (refer to FIG. 6) may pass through the resin layer 500 and be easily emitted to the outside.

In an embodiment, the resin layer 500 may include a resin layer central area (not shown) and a resin layer extension area 500EA. Specifically, the resin layer central area is an area corresponding to the center area CA (refer to FIG. 5) and may overlap the center area CA in a plan view. The resin layer extension area 500EA is an area corresponding to the extension area EA (refer to FIG. 5), and may overlap the extension area EA in a plan view. The resin layer extension area 500EA may extend in a direction away from the resin layer central area. That is, the resin layer extension area 500EA may extend in a length direction of the extension area EA.

Similarly, the resin layer 500 may include a resin layer middle area corresponding to the middle area MA (refer to FIG. 5) and a resin layer side area corresponding to the first and second side areas SA1 and SA2 (refer to FIG. 5). Hereinafter, the resin layer extension area 500EA will be mainly described.

In an embodiment, a plurality of resin layer extension areas 500EA may be provided. The plurality of resin layer extension areas 500EA may respectively overlap the plurality of extension areas EA in a plan view. In an embodiment, the resin layer extension area 500EA may overlap the encapsulation layer 300 between two first corner dams CD1 in a width direction of the extension area EA.

A cover window CW may be arranged above the resin layer 500. In addition, an adhesive layer 600 may be between the resin layer 500 and the cover window CW. In an embodiment, the adhesive layer 600 may be a transparent adhesive member, such as an optically clear adhesive (“OCA”) film.

In an embodiment, the cover window CW and the adhesive layer 600 may be arranged to cover the extension area EA and the separation area VA. In other words, the cover window CW and the adhesive layer 600 may overlap the resin layer 500 in the extension area EA. Also, the cover window CW and the adhesive layer 600 may not overlap the resin layer 500 in the separation area VA. The cover window CW and the adhesive layer 600 may be spaced apart from the display panel 10 by a predetermined distance, that is, the thickness T of the resin layer 500, by the resin layer 500. The resin layer 500 may move the neutral plane of the display apparatus upward.

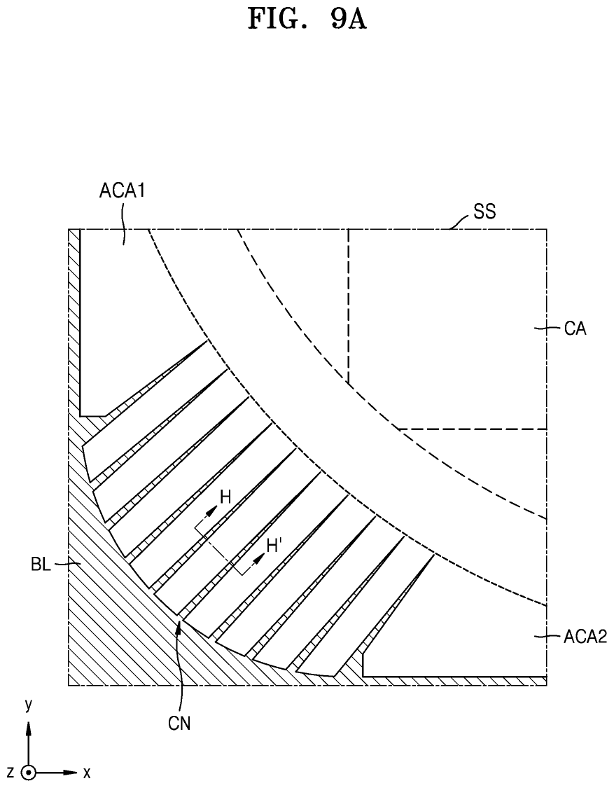

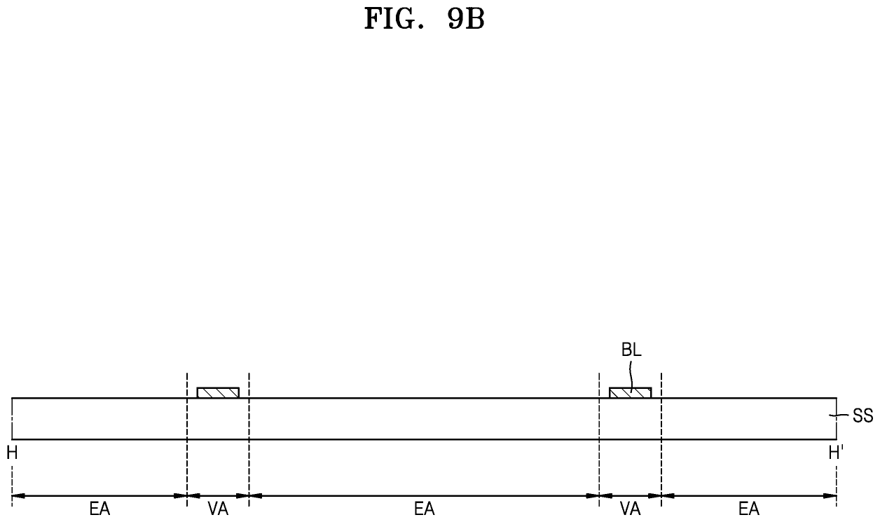

FIG. 9A is a schematic plan view illustrating an embodiment of a method of manufacturing a display apparatus. FIG. 9B is a cross-sectional view of the display apparatus taken along line H-H′ of FIG. 9A. The method of manufacturing a display apparatus, in the illustrated embodiment may be the method of manufacturing the display apparatus described above.

Referring to FIGS. 9A and 9B, a blocking layer BL may be formed on a support substrate SS. The support substrate SS may include a material (e.g., a glass material) having sufficient hardness and rigidity to support a display panel and/or a display apparatus. The blocking layer BL may be formed to correspond to a corner CN of the display panel and/or the display apparatus.

The blocking layer BL may include a material that blocks laser used in the process of separating the display panel and/or the display apparatus from the support substrate SS. In an embodiment, the blocking layer BL may include a material having an absorption rate of 90% or more (i.e., a transmittance of 10% or less) in the vicinity of a wavelength band of about 300 nanometers (nm). The blocking layer BL may include at least one of amorphous silicon (a-Si), poly-silicon (Poly-Si), crystalline silicon (Crystalline-Si), ZnO, IZO, or the like, for example. In an embodiment, when an excimer laser having a wavelength of about 308 nm is used, the blocking layer BL may preferably include amorphous silicon (a-Si).

The blocking layer BL may be formed by patterning through an exposure and development process using a photoresist material. In an embodiment, the blocking layer BL may include a plurality of extension portions. In an embodiment, the blocking layer BL may overlap the separation area VA. The blocking layer BL may be arranged outside the plurality of extension areas EA, the first adjacent corner area ACA1, and the second adjacent corner area ACA2.

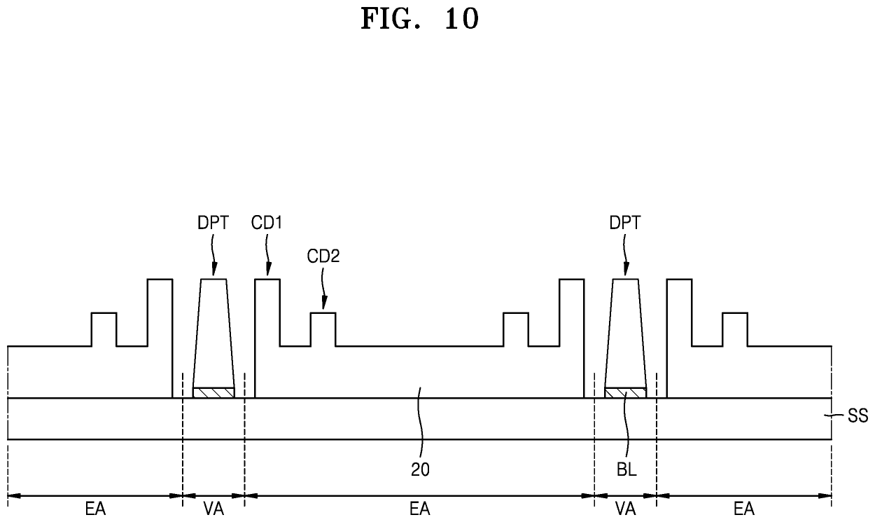

FIG. 10 is a schematic cross-sectional view illustrating an embodiment of a method of manufacturing a display apparatus. In FIG. 10, in the display panel 10 being manufactured, layers arranged under the encapsulation layer 300 are schematically represented as a stacked body 20. The stacked body 20 represents the display panel 10 excluding the encapsulation layer 300.

Referring to FIG. 10, the stacked body 20 may be formed by stacking a plurality of layers (also referred to as substrate layers) on a support substrate SS. In an embodiment, the substrate 100 (refer to FIG. 7), the sub-pixel circuit layer PCL (refer to FIG. 7), and the display element layer DEL (refer to FIG. 7) may be stacked on the support substrate SS, for example.

In this case, at least a portion of the stacked body 20 overlapping the separation area VA between the plurality of extension areas EA may be removed. Specifically, of the stacked body 20, a portion at the boundary between the separation area VA and the plurality of extension areas EA may be removed, and a portion at the center of the separation area VA may not be removed. Accordingly, a dummy pattern DPT overlapping the separation area VA may be formed.

In an embodiment, the stacked body 20 may include one first corner dam CD1 at each of opposite ends of the extension area EA in a width direction thereof. In addition, the stacked body 20 may include one second corner dam CD2 at each of opposite ends of the extension area EA in the width direction thereof. The second corner dam CD2 may be arranged inside the first corner dam CD1 in the width direction of the extension area EA.

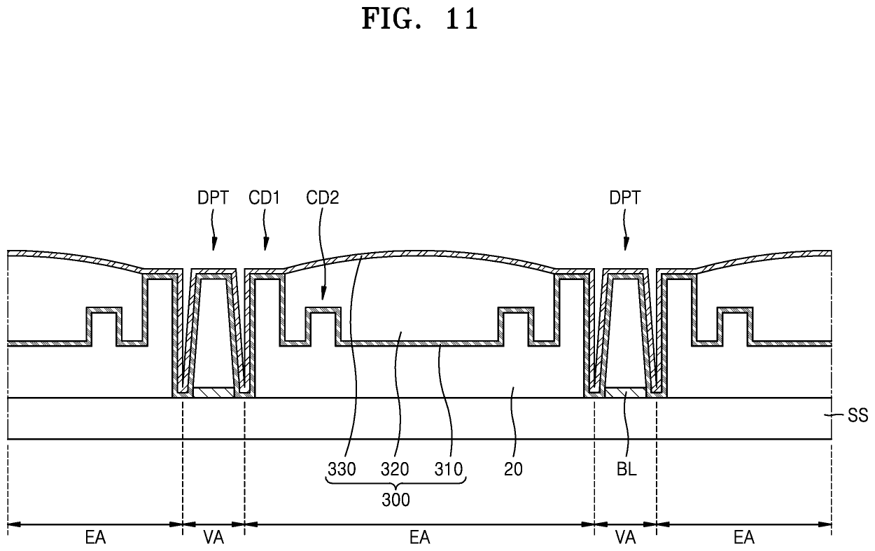

FIG. 11 is a schematic cross-sectional view illustrating an embodiment of a method of manufacturing a display apparatus.

Referring to FIG. 11, an encapsulation layer 300 may be formed on the stacked body 20. First, a first inorganic encapsulation layer 310 may be formed to cover the stacked body 20. The first inorganic encapsulation layer 310 may be continuously formed to cover from a boundary between an extension area EA and a separation area VA to a side surface of the stacked body 20.

An organic encapsulation layer 320 may be formed on the first inorganic encapsulation layer 310. The organic encapsulation layer 320 may be formed by an inkjet method, for example. In an embodiment, the organic encapsulation layer 320 may be applied between first corner dams CD1.

A second inorganic encapsulation layer 330 may be formed on the organic encapsulation layer 320. Similar to the first inorganic encapsulation layer 310, the second inorganic encapsulation layer 330 may be continuously formed to cover from the boundary between the extension area EA and the separation area VA to the side surface of the stacked body 20.

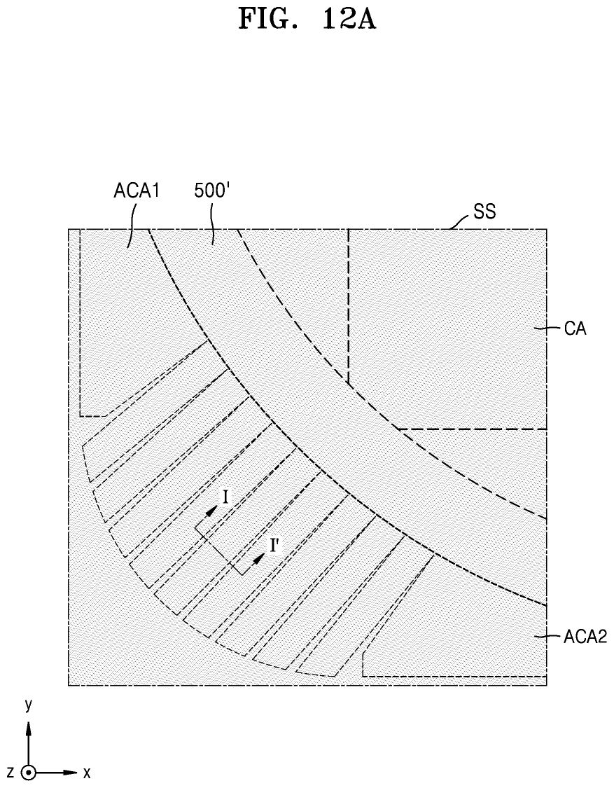

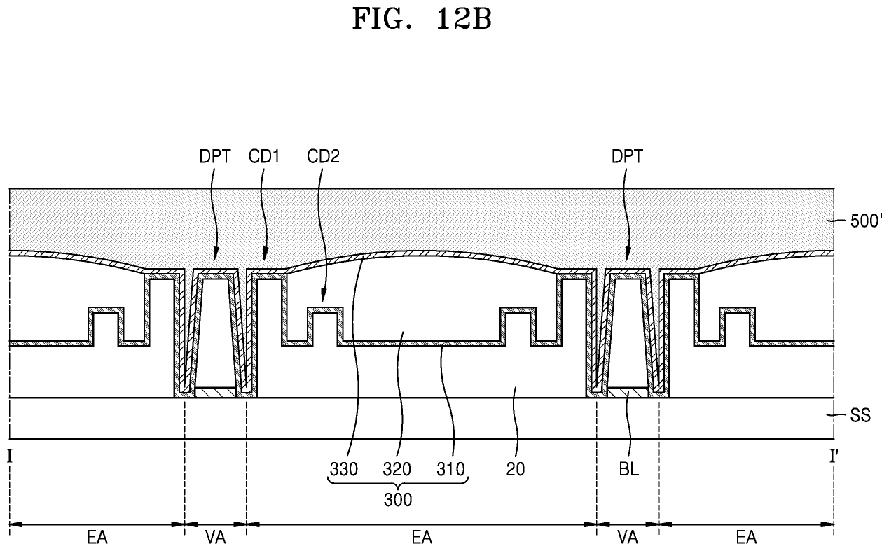

FIG. 12A is a schematic plan view illustrating an embodiment of a method of manufacturing a display apparatus. FIG. 12B is a cross-sectional view of the display apparatus taken along line I-I′ of FIG. 12A.

Referring to FIGS. 12A and 12B, a preliminary resin layer 500′ may be formed on an encapsulation layer 300, e.g., a second inorganic encapsulation layer 330. The preliminary resin layer 500′ may be formed by applying the above-described resin composition. The preliminary resin layer 500′ may also be applied to a separation area VA beyond a first corner dam CD1 of an extension area EA. The preliminary resin layer 500′ may be continuously arranged in a plurality of extension areas EA and separation areas VA.

The resin composition constituting the preliminary resin layer 500′ may include a negative photoresist material or a positive photoresist material. In an embodiment, the resin composition may include a negative photoresist material.

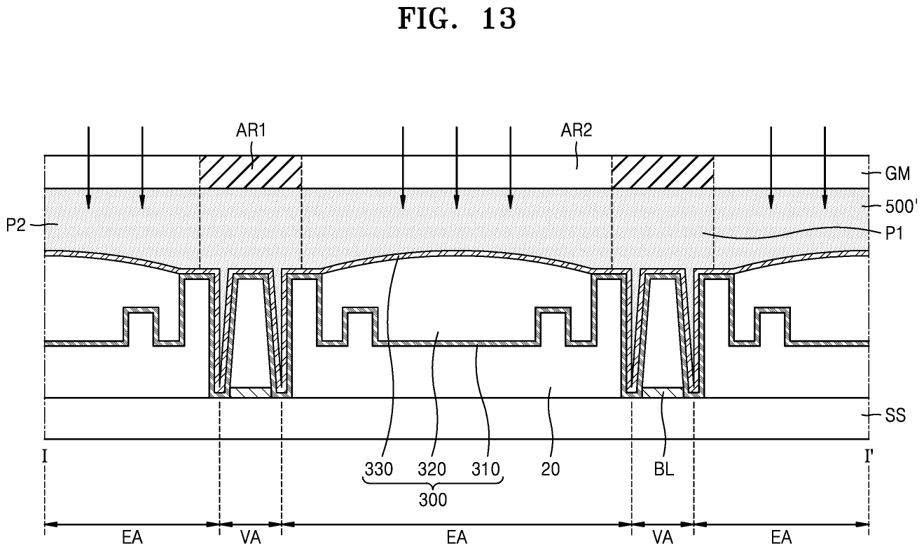

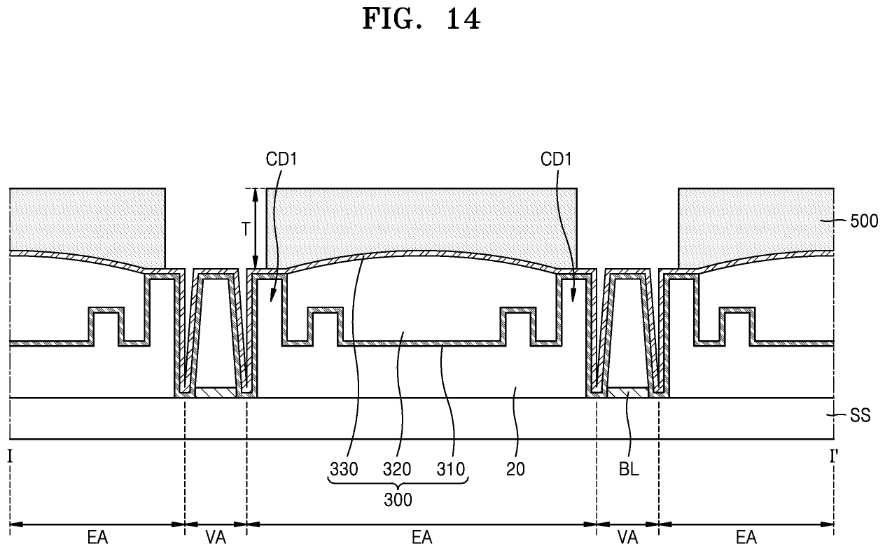

FIGS. 13 and 14 are schematic cross-sectional views illustrating an embodiment of a method of manufacturing a display apparatus.

Referring to FIGS. 13 and 14, a resin layer 500 may be formed by exposing a preliminary resin layer 500′ by a mask GM and then developing the resin layer 500′.

First, the mask GM may be aligned on the preliminary resin layer 500′. In an embodiment, the mask GM may use a glass mask or a metal mask. In an embodiment, when the mask GM is a glass mask, an exposure process may be performed by attaching the mask GM to the preliminary resin layer 500′, and then the mask GM may be removed from the preliminary resin layer 500′, for example.

The mask GM may include a first area AR1 and a second area AR2. In an embodiment, the first area AR1 may be a light-blocking area, and the second area AR2 may be a light-transmitting area. A plurality of first areas AR1 and a plurality of second areas AR2 may be provided. The first area AR1 of the mask GM may correspond to a separation area VA, and the second area AR2 may correspond to an extension area EA.

Thereafter, the preliminary resin layer 500′ may be cured by irradiating light (e.g., ultraviolet light) from an upper side of the mask GM. In an embodiment, an exposure dose for curing the preliminary resin layer 500′ may be about 10 millijoules (mJ) to about 20 mJ. In an embodiment, ultraviolet light having a wavelength of about 300 nm to about 400 nm may be used for light curing.

Thereafter, the exposed preliminary resin layer 500′ may be developed using a developer. In an embodiment, an organic solvent may be used as the developer. In an embodiment, when the preliminary resin layer 500′, that is, the resin composition, includes a negative photoresist material, during a development process, a portion P1 exposed by the first area AR1 remains, and a portion P2 corresponding to the second area AR2 may be removed. Accordingly, the resin layer 500 may be formed.

In a comparative example, a resin layer may be formed by applying, by an inkjet method, a resin composition between corner dams arranged at opposite ends of an extension area in a width direction thereof and curing the resin composition. However, the inkjet method may cause an impact error, and thus the resolution of a resin layer pattern may be limited. In addition, it may be difficult to implement a relatively high modulus and a relatively large thickness desired for the resin layer.

However, in the illustrated embodiment, the resin layer 500 may be formed by entirely coating a resin composition and patterning the resin composition through exposure and development processes. In this case, the pattern of the resin layer 500 may be implemented with higher resolution compared to the case of using the inkjet method. In addition, as the resin composition includes the acrylate oligomer, the monomer, and the photoinitiator described above with reference to FIG. 8, the resin layer 500 having a relatively high modulus and a relatively large thickness may be formed.

In an embodiment, the resin layer 500 may have a relatively high modulus. In an embodiment, the resin layer 500 may have a modulus of about 0.5 GPa to about 3 GPa, preferably about 0.7 GPa to about 1.5 GPa, and more preferably about 0.9 GPa to about 1.2 GPa, for example.

Also, in an embodiment, a thickness T of the resin layer 500 may be about 100 μm to about 200 μm, preferably about 130 μm to about 170 μm. In an embodiment, the thickness T of the resin layer 500 may be about 150 μm, for example.

The resin layer 500 may be arranged to cover the encapsulation layer 300 in the extension area EA. The resin layer 500 may contact the upper surface of the first corner dam CD1 disposed at each of opposite ends of the extension area EA in the width direction thereof.

As the resin layer 500 is arranged on the display panel 10, the neutral plane may be moved upward to be adjacent to the encapsulation layer 300, particularly the second inorganic encapsulation layer 330. Accordingly, stress applied to the display panel 10, particularly the second inorganic encapsulation layer 330, may be reduced or eliminated. Cracks that may occur in the display panel 10, particularly in the second inorganic encapsulation layer 330, may be prevented in the bending extension area EA.

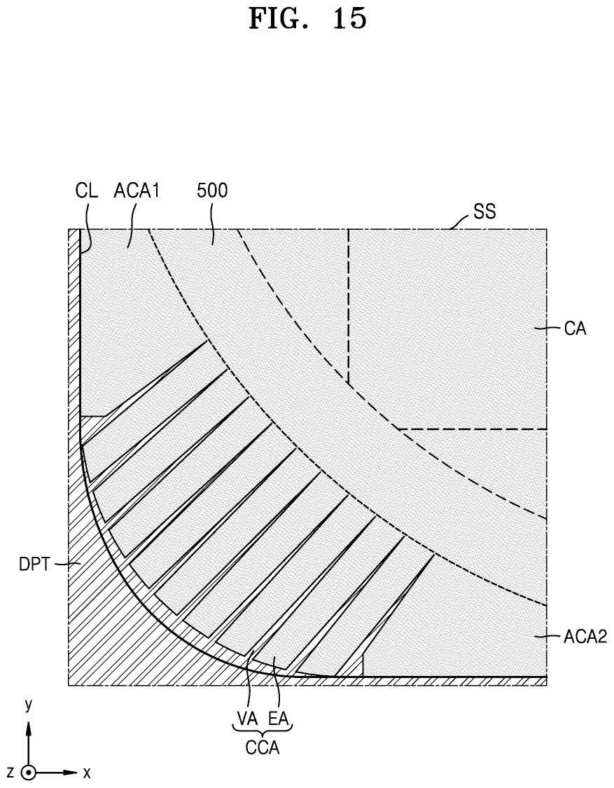

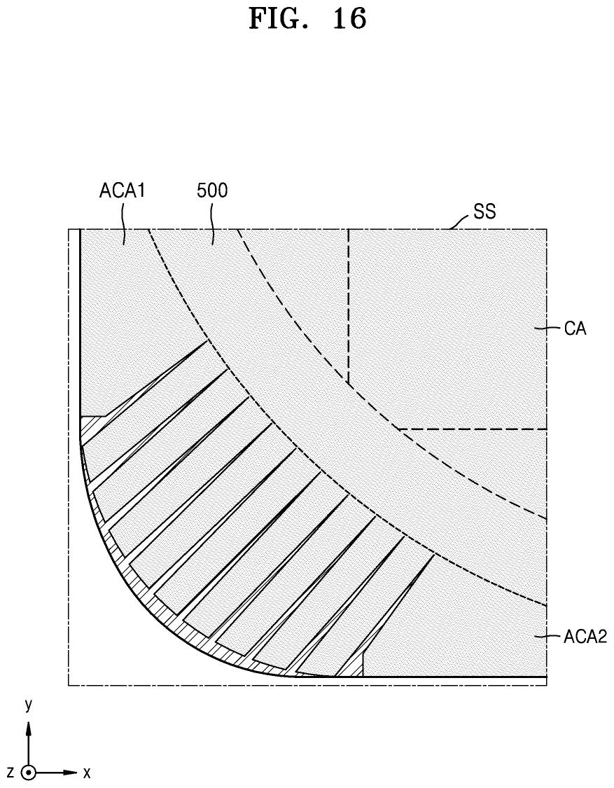

FIGS. 15 and 16 are schematic plan views illustrating an embodiment of a method of manufacturing a display apparatus.

Referring to FIGS. 15 and 16, at least portions of the stacked body 20, the encapsulation layer 300, and the resin layer 500 may be cut by a laser. Specifically, the stacked body 20, the encapsulation layer 300, and the resin layer 500 may be cut along a cutting line CL extending along the circumferences of a first adjacent corner area ACA1, a center corner area CCA, and a second adjacent corner area ACA2. Accordingly, the stacked body 20, the encapsulation layer 300, and the resin layer 500 may be cut to the size of a cell. In this case, dummy patterns DPT arranged outside the first adjacent corner area ACA1, the center corner area CCA, and the second adjacent corner area ACA2 may be removed, and a portion of the dummy pattern DPT overlapping a separation area VA may not be removed.

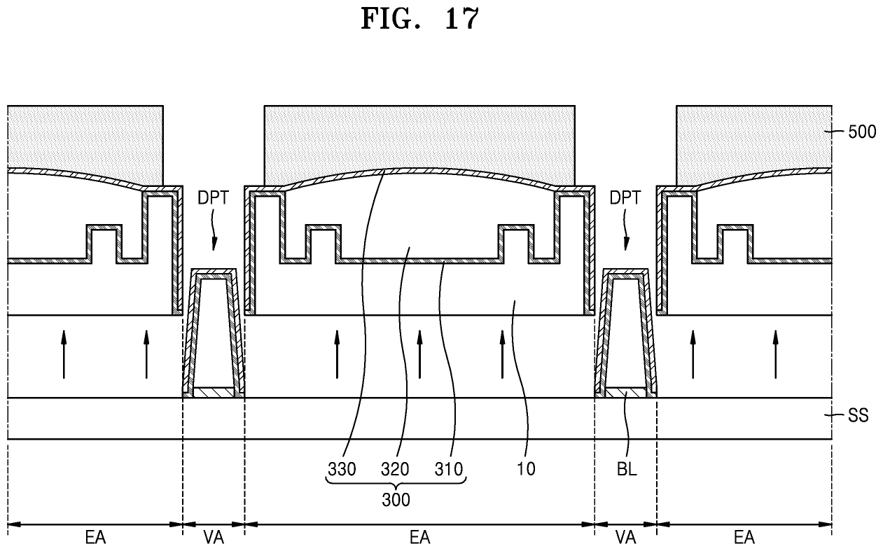

FIG. 17 is a schematic cross-sectional view illustrating an embodiment of a method of manufacturing a display apparatus.

Referring to FIG. 17, the stacked body 20 may be separated from the support substrate SS. In an embodiment, the stacked body 20 may be separated from the support substrate SS according to a laser release method using a laser. The laser may be irradiated in a direction from the lower surface of the support substrate SS to the upper surface of the support substrate SS. As the laser, e.g., an excimer laser having a wavelength of 308 nm, or a solid-state UV laser having a wavelength of 343 nm or a wavelength of 355 nm may be used.

A blocking layer BL may be arranged under the dummy pattern DPT to absorb the laser. Therefore, even when the laser is irradiated, the dummy pattern DPT may not be separated from the support substrate SS. The dummy pattern DPT may be removed together with the support substrate SS when the support substrate SS is separated. Accordingly, an area where the dummy pattern DPT is disposed may form the separation area VA as an empty space, and the display panel 10 as described above may be formed.

In the illustrated embodiment, with reference to FIGS. 15 and 16, cutting the support substrate SS and the stacked body 20 to a cell size and then separating the support substrate SS from the stacked body 20 have been mainly described. However, in another embodiment, after the support substrate SS is first separated from the stacked body 20, the remaining stacked body 20 may be cut to the size of a cell.

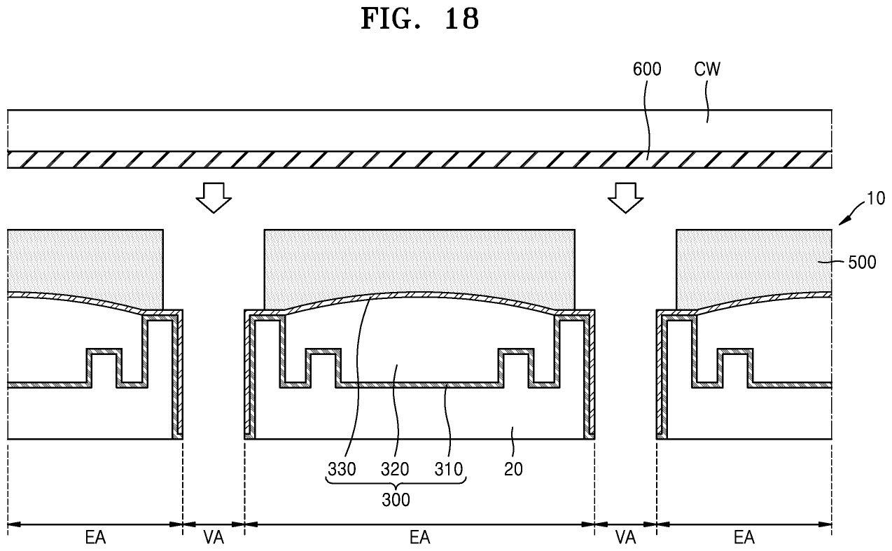

FIG. 18 is a schematic cross-sectional view illustrating an embodiment of a method of manufacturing a display apparatus.

Referring to FIG. 18, a cover window CW may be bonded to a display panel 10. In this case, the cover window CW may be bonded to a resin layer 500 by an adhesive layer 600 between the cover window CW and the resin layer 500.

In an embodiment, the cover window CW and the adhesive layer 600 may be arranged to cover an extension area EA and a separation area VA. In other words, the cover window CW and the adhesive layer 600 may overlap the resin layer 500 in the extension area EA. Also, the cover window CW and the adhesive layer 600 may not overlap the resin layer 500 in the separation area VA.

In the process of bonding the resin layer 500 to the cover window CW and the adhesive layer 600, a plurality of extension areas EA and a plurality of resin layer extension areas 500EA may be bent. In this case, because the separation area VA is disposed between the plurality of extension areas EA and between the plurality of resin layer extension areas 500EA, the plurality of extension areas EA and the plurality of resin layer extension areas 500EA may be easily bent without interfering with each other.

The display apparatus in an embodiment may include the resin layer 500, specifically, the resin layer extension area 500EA, and a neutral plane may be moved upward by the resin layer 500 to be adjacent to the encapsulation layer 300. Accordingly, defects such as cracks may be reduced when bending the display apparatus, particularly at the corner CN of the display apparatus.

By embodiments of the disclosure, a display apparatus capable of preventing defects such as cracks and a method of manufacturing the display apparatus may be implemented. However, the scope of the disclosure is not limited by these effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display apparatus comprising:
a display panel including:
a substrate including a center area; and
a corner area arranged at a corner of the center area, the corner area including:
a plurality of extension areas; and
a separation area between the plurality of extension areas extending in a direction away from the center area; and
a resin layer arranged on the display panel, the resin layer including:
a plurality of resin layer extension areas overlapping the plurality of extension areas.

2. The display apparatus of claim 1, wherein a side surface of the resin layer has an angle of about 80 degrees to about 100 degrees with respect to an upper surface of the substrate.

3. The display apparatus of claim 1, wherein the resin layer is a cured product of a resin composition including a urethane acrylate oligomer, an epoxy acrylate oligomer, a polyfunctional acrylate monomer, a bisphenol monomer, a low molecular weight ethylene glycol monomer, and a photoinitiator.

4. The display apparatus of claim 3, wherein the polyfunctional acrylate monomer has three or four functional groups.

5. The display apparatus of claim 3, wherein the resin composition includes, based on a total weight of the resin composition, about 5 wt % to about 15 wt % of the urethane acrylate oligomer, about 5 wt % to about 15 wt % of the epoxy acrylate oligomer, about 20 wt % to about 35 wt % of the polyfunctional acrylate monomer, about 20 wt % to about 25 wt % of the bisphenol monomer, about 15 wt % to about 25 wt % of the low molecular weight ethylene glycol monomer, and about 3 wt % to about 5 wt % of the photoinitiator.

6. The display apparatus of claim 5, wherein the resin composition further includes about 2 wt % to about 5 wt % of an additive, based on the total weight of the resin composition.

7. The display apparatus of claim 1, wherein the resin layer has a modulus of about 0.7 gigapascal to about 1.5 gigapascals.

8. The display apparatus of claim 1, wherein the resin layer has a thickness of about 130 micrometers to about 170 micrometers.

9. The display apparatus of claim 1, wherein the display panel further includes:
a display element; and
an encapsulation layer which covers the display element and including at least one inorganic encapsulation layer and at least one organic encapsulation layer,
wherein the resin layer is arranged on the encapsulation layer.

10. The display apparatus of claim 1, further comprising:
a cover window arranged on the resin layer; and
an adhesive layer arranged between the resin layer and the cover window,
wherein the cover window and the adhesive layer overlap the separation area, and the resin layer does not overlap the separation area.

11. A method of manufacturing a display apparatus, the method comprising:
forming a substrate layer on a support substrate, the substrate layer including a center area, a plurality of extension areas arranged at corners of the center area and extending in a direction away from the center area, and a separation area between the plurality of extension areas;
forming a display element on the substrate layer;
forming an encapsulation layer to cover the display element; and
forming a resin layer having a thickness of about 130 micrometers to about 170 micrometers on the encapsulation layer.

12. The method of claim 11, wherein the forming the resin layer includes forming the resin layer to be arranged within the plurality of extension areas in a plan view.

13. The method of claim 12, wherein the forming the resin layer further includes:
applying a resin composition; and
irradiating light to cure the resin composition.

14. The method of claim 13, wherein the curing the resin composition includes:
preparing a mask including a first area and a second area;
aligning the mask so that the first area corresponds to the separation area and the second area corresponds to the plurality of extension areas; and
irradiating light.

15. The method of claim 13, wherein the resin composition includes a urethane acrylate oligomer, an epoxy acrylate oligomer, a polyfunctional acrylate monomer, a bisphenol monomer, a low molecular weight ethylene glycol monomer, and a photoinitiator.

16. The method of claim 15, wherein the resin composition includes, based on a total weight of the resin composition, about 5 wt % to about 15 wt % of the urethane acrylate oligomer, about 5 wt % to about 15 wt % of the epoxy acrylate oligomer, about 20 wt % to about 35 wt % of the polyfunctional acrylate monomer, about 20 wt % to about 25 wt % of the bisphenol monomer, about 15 wt % to about 25 wt % of the low molecular weight ethylene glycol monomer, and about 3 wt % to about 5 wt % of the photoinitiator.

17. The method of claim 11, further comprising removing at least a portion of the substrate layer from the separation area.

18. The method of claim 17, further comprising:
detaching the substrate layer from the support substrate;
bending the plurality of extension areas; and
arranging a cover window on the resin layer over the plurality of extension areas.

19. The method of claim 18, further comprising arranging an adhesive layer between the cover window and the resin layer,
wherein the cover window and the adhesive layer overlap the separation area, and the resin layer does not overlap the separation area.

20. The method of claim 11, wherein the resin layer has a modulus of about 0.7 gigapascal to about 1.5 gigapascals.
